(19) United States
(12) Patent Application Publication
(10) Pub. No.: US 2025/0194340 A1
(43) Pub. Date: Jun. 12, 2025

(54) DISPLAY APPARATUS HAVING A PIXEL DRIVING CIRCUIT

(71) Applicant: LG Display Co., Ltd., Seoul (KR)

(72) Inventor: Sung Ju CHOI, Paju-si (KR)

(21) Appl. No.: 18/918,768

(22) Filed: Oct. 17, 2024

(30) Foreign Application Priority Data
Dec. 12, 2023 (KR) 10-2023-0179933

(51) Int. Cl. H10K 59/121; H10K 59/80

(52) U.S. Cl. CPC H10K 59/1213; H10K 59/8791; H10K 59/1216

(57) ABSTRACT

A display apparatus including a plurality of pixel areas is provided. A pixel driving circuit electrically connected to a light-emitting device may be disposed in each pixel area. The pixel driving circuit may generate a driving current corresponding to a data signal according to a gate signal. For example, the pixel driving circuit may include a driving thin film transistor. The driving thin film transistor may include a driving semiconductor pattern and a driving gate electrode. The driving semiconductor pattern may include a first sub-channel and a second sub-channel, which are disposed parallel to each other between a drain region and a source region. The driving gate electrode may include a first sub-gate overlapping with the first sub-channel and a second sub-gate overlapping with the second sub-channel. A second threshold voltage applied to the second sub-gate at the moment that a channel is formed in the second sub-channel may be different from a first threshold voltage applied to the first sub-gate at the moment that a channel is formed in the first sub-channel. Thus, in the display apparatus, S-factor of the driving thin film transistor and a driving current generated by the driving thin film transistor may be increased.

### CROSS-REFERENCE TO RELATED APPLICATIONS

This application claims the benefit of Korean Patent Application No. 10-2023-0179933, filed on Dec. 12, 2023, which is hereby incorporated by reference as if fully set forth herein.

### BACKGROUND

### Technical Field

The present disclosure relates to a display apparatus in which a pixel driving circuit electrically connected to a light-emitting device is disposed in each pixel area.

### Description of the Related Art

Generally, a display apparatus provides an image to a user. For example, the display apparatus may include a plurality of light-emitting devices. Each of the light-emitting devices may emit light displaying a specific color. For example, the light-emitting device may include at least one emission material layer between a first electrode and a second electrode.

An operation of each light-emitting device may be controlled by a pixel driving circuit. For example, one of the light-emitting devices and the pixel driving circuit electrically connected to the corresponding light-emitting device may be disposed in each pixel area. The pixel driving circuit of each pixel area may supply a driving current corresponding to a data signal to the light-emitting device of the corresponding pixel area according to a gate signal for one frame. For example, the pixel driving circuit of each pixel area may include a driving thin film transistor for generating the driving current corresponding to the data signal and at least one switching thin film transistor for transmitting the data signal and/or the driving current.

The driving current generated by the driving thin film transistor of each pixel area may determine a gray-scale of the corresponding pixel area.

### BRIEF SUMMARY

The inventors recognize that in the display apparatus, electrical characteristics of the driving thin film transistor may be different from electrical characteristics of the switching thin film transistor. Thus, in the display apparatus, a process of forming the pixel driving circuit in each pixel may be complicated. Therefore, in the display apparatus, efficiency in process may be decreased. And, in the display apparatus, quality of the image may be deteriorated by a difference in the characteristics of the pixel driving circuit due to a process deviation. The present disclosure is directed to a display apparatus that substantially obviates one or more problems due to limitations and disadvantages of the related art.

The present disclosure provides a display apparatus capable of simplifying a process of forming the thin film transistors having different characteristics in each pixel area.

The present disclosure provides a display apparatus capable of improving S-factor of the driving thin film transistor and driving current generated by the driving thin film transistor, and minimizing decrease in process efficiency.

Additional technical improvements, characteristics, and features of the disclosure will be set forth in part in the description which follows and in part will become apparent to those having ordinary skill in the art upon examination of the following or may be learned from practice of the disclosure. The features and characteristics of the disclosure may be realized and attained by the structure particularly pointed out in the written description and claims hereof as well as the appended drawings.

To achieve these technical features and improvements and in accordance with the purpose of the present disclosure, as embodied and broadly described herein, there is provided a display apparatus comprising a pixel driving circuit electrically connected to a light-emitting device. The pixel driving circuit includes a thin film transistor. The thin film transistor includes a semiconductor pattern, a gate electrode, a drain electrode and a source electrode. The gate electrode includes a first sub-gate and a second sub-gate. The first sub-gate and the second sub-gate are disposed between the drain electrode and the source electrode. The semiconductor pattern includes a first sub-channel and a second sub-channel. The first sub-channel overlaps the first sub-gate. The second sub-gate overlaps the second sub-gate. The number of insulating layers disposed between the second sub-channel and the second sub-gate is different from the number of insulating layers disposed between the first sub-channel and the first sub-gate.

The semiconductor pattern may include a drain region and a source region. The drain region may be electrically connected to the drain electrode. The source region may be electrically connected to the source electrode. The first sub-channel and the second sub-channel may be disposed parallel to each other between the drain region and the source region.

The second sub-gate may be disposed on a different layer from the first sub-gate.

The gate electrode may include a third sub-gate disposed on a same layer as the second sub-gate. The semiconductor pattern may include a third sub-channel overlapping with the third sub-gate. The first sub-channel may be disposed between the second sub-channel and the third sub-channel.

The drain electrode and the source electrode may be disposed on a different layer from the first sub-gate and the second sub-gate.

The gate electrode may include a connection gate electrically connecting the second sub-gate to the first sub-gate. The connection gate may be disposed on a same layer as the drain electrode and the source electrode.

The pixel driving circuit may include a storage capacitor. The storage capacitor may include a first capacitor electrode and a second capacitor electrode. The first capacitor electrode may be disposed on a same layer as the first sub-gate. The second capacitor electrode may be disposed on a same layer as the second sub-gate.

The pixel driving circuit and the light-emitting layer may be supported by a device substrate. A light-blocking pattern may be disposed between the device substrate and the semiconductor pattern. The storage capacitor may include a third capacitor electrode disposed on a same layer as the light-blocking pattern.

In another embodiment, there is provided a display apparatus comprising a device substrate. A first thin film transistor and a second thin film transistor are disposed on a pixel area of the device substrate. The first thin film transistor includes a first semiconductor pattern and a first gate electrode. The second thin film transistor includes a second semiconductor pattern and a second gate electrode. The first thin film transistor and the second thin film transistor are covered by a planarization layer. A light-emitting device is disposed on the planarization layer of the pixel area. The light-emitting device is electrically connected to the second thin film transistor. The second semiconductor pattern includes a first sub-channel and a second sub-channel. The first sub-channel and the second sub-channel are disposed parallel to each other between a drain region and a source region of the second semiconductor pattern. The second gate electrode includes a first sub-gate and a second sub-gate. The first sub-gate is disposed on the first sub-channel. The second sub-gate is disposed on the second sub-channel. A distance between the second sub-channel and the second sub-gate is greater than a distance between the first sub-channel and the first sub-gate.

The distance between the first sub-channel and the first sub-gate may be a same as a distance between the first semiconductor pattern and the first gate electrode.

The second sub-gate may include a same material as the first sub-gate.

The second sub-gate may be in contact with the first sub-gate on the second semiconductor pattern.

The second semiconductor may be made of an oxide semiconductor. The amount of oxygen contained in the first sub-channel and the amount of oxygen contained in the second sub-channel may be larger than the amount of oxygen contained in the drain region and the amount of oxygen contained in the source region.

The amount of oxygen contained in the second sub-channel may be a same as the amount of oxygen contained in the first sub-channel.

The first semiconductor pattern may be disposed between the device substrate and the first gate electrode. The second gate electrode may be disposed between the device substrate and the second semiconductor pattern.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is a view showing a cross-section taken along I-I′ of FIG. 1 and a cross-section of the pixel area in the display apparatus according to the embodiment of the present disclosure;

FIG. 4 is an enlarged view of K1 region in FIG. 3;

FIG. 5 is a plan view showing a second thin film transistor of each pixel area in the display apparatus according to the embodiment of the present disclosure;

FIG. 6 is a view showing a cross-section taken along II-II′ of FIG. 5;

FIG. 7 is a graph showing a driving current according to a voltage applied to a gate electrode according to a structure of a thin film transistor; and

FIGS. 8 to 17 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

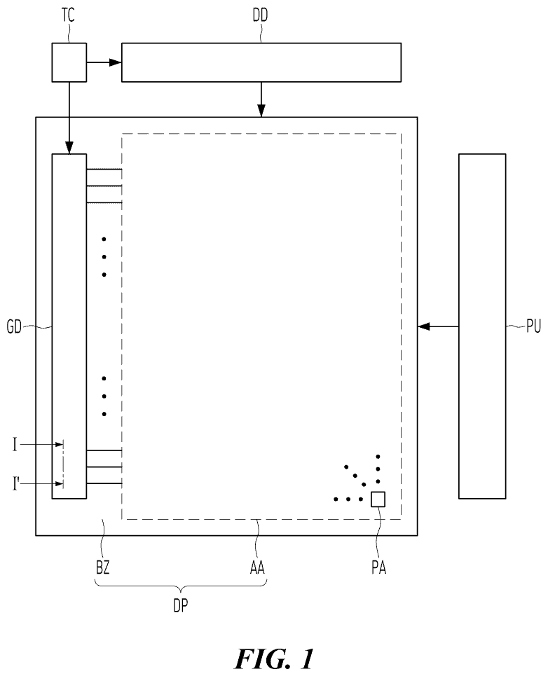

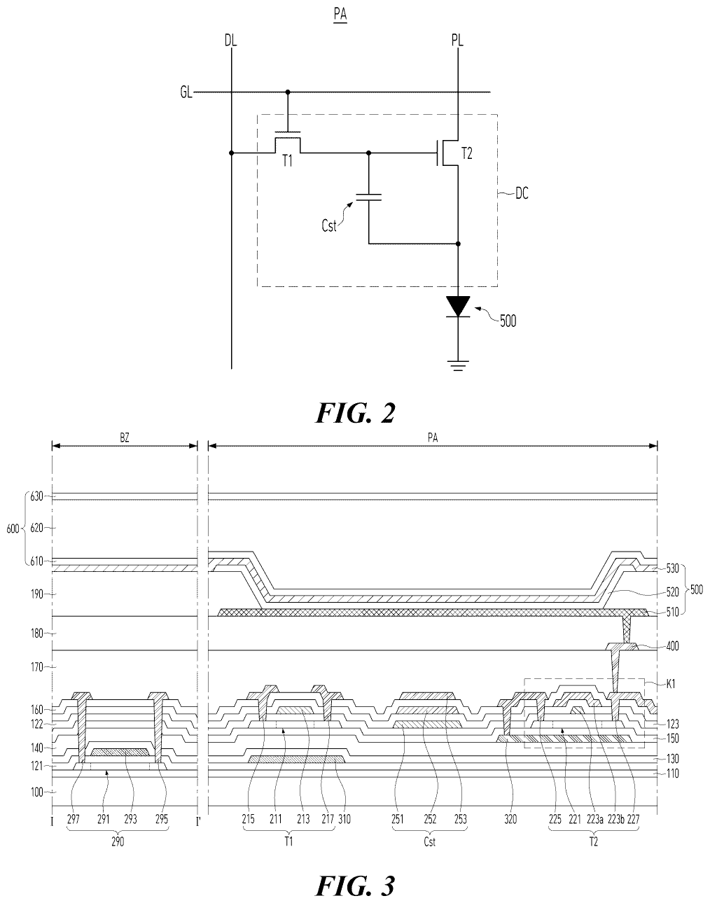

FIG. 1 is a view schematically showing a display apparatus according to an embodiment of the present disclosure. FIG. 2 is a view showing a circuit of a pixel area in the display apparatus according to the embodiment of the present disclosure.

Referring to FIGS. 1 and 2, the display apparatus according to the embodiment of the present disclosure may include a display panel DP. The display panel DP may generate an image provided to a user. For example, a plurality of pixel areas PA may be disposed in the display panel DP. Various signals may be provided in each pixel area PA through signal wirings GL, DL and PL. For example, the signal wirings GL, DL and PL may include gate lines GL sequentially applying a gate signal to each pixel area PA, data lines DL applying a data signal to each pixel area PA, and power voltage supply lines PL supplying a power voltage to each pixel area PA. The gate lines GL may be electrically connected to a gate driver GD. The data lines DL may be electrically connected to a data driver DD. The gate driver GD and the data driver DD may be controlled by a timing controller TC. For example, the gate driver GD may receive clock signals, reset signals and a start signal from the timing controller TC, and the data driver DD may receive digital video data and a source timing signal from the timing controller TC. The power voltage supply lines PL may be electrically connected to a power unit PU.

The display panel DP may include an active area AA in which the pixel areas PA are disposed, and a bezel area BZ being disposed outside the active area AA. The bezel area BZ may be disposed outside the pixel areas PA. For example, the active area AA may be surrounded by the bezel area BZ. At least one of the gate driver GD, the data driver DD, the timing controller TC and the power unit PU may be disposed on the bezel area BZ of the display panel DP. For example, the display apparatus according to the embodiment of the present disclosure may be a GIP (Gate In Panel) type display apparatus in which the gate driver GD is formed on the bezel area BZ of the display panel DP. Each of the signal wirings GL, DL and PL may include a portion disposed on the bezel area BZ.

Each of the pixel areas PA may realize a specific color. For example, a light-emitting device 500 and a pixel driving circuit DC electrically connected to the light-emitting device 500 may be disposed in each pixel area PA. The signal wirings GL, DL and PL may be electrically connected to the pixel driving circuit DC of each pixel area PA. For example, the pixel driving circuit DC of each pixel area PA may be electrically connected to one of the gate lines GL, one of the data lines DL, and one of the power voltage supply lines PL. The pixel driving circuit DC of each pixel area PA may supply a driving current corresponding to the data signal to the light-emitting device 500 of the corresponding pixel area PA according to the gate signal for one frame. For example, the pixel driving circuit DC of each pixel area PA may include a first thin film transistor T1, a second thin film transistor T2 and a storage capacitor Cst.

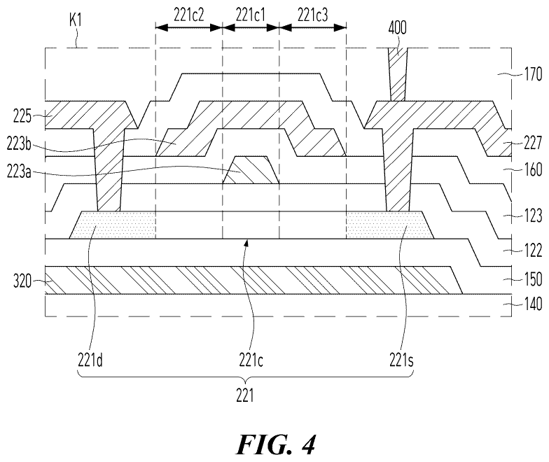

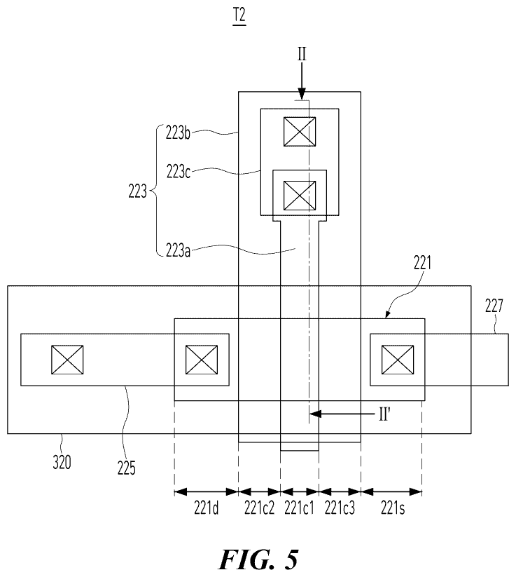

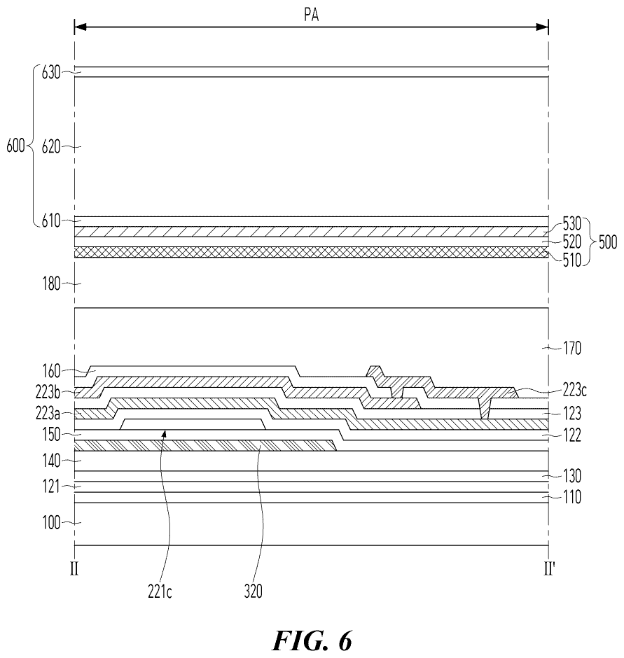

FIG. 3 is a view showing a cross-section taken along I-I′ of FIG. 1 and a cross-section of the pixel area in the display apparatus according to the embodiment of the present disclosure. FIG. 4 is an enlarged view of K1 region in FIG. 3. FIG. 5 is a plan view showing a second thin film transistor of each pixel area in the display apparatus according to the embodiment of the present disclosure. FIG. 6 is a view showing a cross-section taken along II-II′ of FIG. 5.

Referring to FIGS. 2 to 6, the first thin film transistor T1 of each pixel area PA may transmit the data signal to the second thin film transistor T2 of the corresponding pixel area PA according to the gate signal. For example, the first thin film transistor T1 of each pixel area PA may be a switching thin film transistor. The first thin film transistor T1 of each pixel area PA may include a first semiconductor pattern 211, a first gate electrode 213, a first drain electrode 215 and a first source electrode 217. For example, the first gate electrode 213 of each pixel area PA may be electrically connected to the corresponding gate line GL, and the first drain electrode 215 of each pixel area PA may be electrically connected to the corresponding data line DL.

The first semiconductor pattern 211 may include a semiconductor material. For example, the first semiconductor pattern 211 may include an oxide semiconductor, such as IGZO. The first semiconductor pattern 211 may include a first drain region, a first channel region and a first source region. The first channel region may be disposed between the first drain region and the first source region. The first drain region and the first source region may have a smaller resistance than the first channel region. For example, the first drain region and the first source region may include a conductive region of an oxide semiconductor. The first channel region may be a region of an oxide semiconductor, which is not conductorized.

The first gate electrode 213 may be disposed on a portion of the first semiconductor pattern 211. For example, the first gate electrode 213 may overlap the first channel region of the first semiconductor pattern 211. The first drain region and the first source region of the first semiconductor pattern 211 may be disposed outside the first gate electrode 213. The first gate electrode 213 may include a conductive material. For example, the first gate electrode 213 may include a metal, such as aluminum (Al), chrome (Cr), copper (Cu), molybdenum (Mo), titanium (Ti) and tungsten (W). The first gate electrode 213 may be insulated from the first semiconductor pattern 211. For example, the first drain region of the first semiconductor pattern 211 may be electrically connected to the first source region of the first semiconductor pattern 211 according to a voltage applied to the first gate electrode 213.

The first drain electrode 215 may include a conductive material. For example, the first drain electrode 215 may include a metal, such as aluminum (Al), chrome (Cr), copper (Cu), molybdenum (Mo), titanium (Ti) and tungsten (W). The first drain electrode 215 may include a different material from the first gate electrode 213. The first drain electrode 215 may be disposed on a different layer from the first gate electrode 213. For example, the first drain electrode 215 may be insulated from the first gate electrode 213. The first drain electrode 215 may be electrically connected to the first drain region of the first semiconductor pattern 211.

The first source electrode 217 may include a conductive material. For example, the first source electrode 217 may include a metal, such as aluminum (Al), chrome (Cr), copper (Cu), molybdenum (Mo), titanium (Ti) and tungsten (W). The first source electrode 217 may include a different material from the first gate electrode 213. The first source electrode 217 may be disposed on a different layer from the first gate electrode 213. For example, the first source electrode 217 may be insulated from the first gate electrode 213. The first source electrode 217 may be disposed on a same layer as the first drain electrode 215. For example, the first source electrode 217 may include a same material as the first drain electrode 215. The first source electrode 217 may be formed by a same process as the first drain electrode 215. For example, the first source electrode 217 may be formed simultaneously with the first drain electrode 215. The first source electrode 217 may be spaced apart from the first drain electrode 215. The first source electrode 217 may be electrically connected to the first source region of the first semiconductor pattern 211.

The second thin film transistor T2 of each pixel area PA may generate the driving current corresponding to the data signal. For example, the second thin film transistor T2 of each pixel area PA may be a driving thin film transistor. The second thin film transistor T2 of each pixel area PA may include a second semiconductor pattern 221, a second gate electrode 223, a second drain electrode 225 and a second source electrode 227. For example, the second gate electrode 223 of each pixel area PA may be electrically connected to the first source electrode 217 of the corresponding pixel area PA, and the second drain electrode 225 of each pixel area PA may be electrically connected to the corresponding power voltage supply line PL.

The second semiconductor pattern 221 may include a semiconductor material. For example, the second semiconductor pattern 221 may include an oxide semiconductor, such as IGZO. The second semiconductor pattern 221 may include a same material as the first semiconductor pattern 211. The second semiconductor pattern 221 may be disposed on a same layer as the first semiconductor pattern 211. The second semiconductor pattern 221 may be formed by a same process as the first semiconductor pattern 211. For example, the second semiconductor pattern 221 may be formed simultaneously with the first semiconductor pattern 211.

The second semiconductor pattern 221 may include a second drain region 221d, a second channel region 221c and a second source region 221s. The second channel region 221c may be disposed between the second drain region 221d and the second source region 221s. The second drain region 221d and the second source region 221s may have a smaller resistance than the second channel region 221c. For example, the second drain region 221d and the second source region 221s may include a conductive region of an oxide semiconductor. The second channel region 221c may be a region of an oxide semiconductor, which is not conductorized.

The second channel region 221c may include a first sub-channel 221c1, a second sub-channel 221c2 and a third sub-channel 221c3, which are disposed parallel to each other between the second drain region 221d and the second source region 221s. The first sub-channel 221c1 may be disposed between the second sub-channel 221c2 and the third sub-channel 221c3. For example, the second sub-channel 221c2 may be disposed between the second drain region 221d and the first sub-channel 221c1, and the third sub-channel 221c3 may be disposed between the first sub-channel 221c1 and the second source region 221s. The first sub-channel 221c1 may have a same resistance as the second sub-channel 221c2 and the third sub-channel 221c3. For example, the amount of oxygen contained in the first sub-channel 221c1 may be a same as the amount of oxygen contained in the second sub-channel 221c2 and the amount of oxygen contained in the third sub-channel 221c3. The amount of oxygen contained in the second drain region 221d and the amount of oxygen contained in the second source region 221s may be smaller than the amount of oxygen contained in the first sub-channel 221c1, the amount of oxygen contained in the second sub-channel 221c2 and the amount of oxygen contained in the third sub-channel 221c3.

The second gate electrode 223 may be disposed on a portion of the second semiconductor pattern 221. For example, the second gate electrode 223 may disposed on the second channel region 221c of the second semiconductor pattern 221. The second drain region 221d and the second source region 221s of the second semiconductor pattern 221 may be disposed outside the second gate electrode 223. The second gate electrode 223 may include a conductive material. For example, the second gate electrode 223 may include a metal, such as aluminum (Al), chrome (Cr), copper (Cu), molybdenum (Mo), titanium (Ti) and tungsten (W). The second gate electrode 223 may be insulated from the second semiconductor pattern 221. For example, the second drain region 221d of the second semiconductor pattern 221 may be electrically connected to the second source region 221s of the second semiconductor pattern 221 according to a voltage applied to the second gate electrode 223.

The second gate electrode 223 may include a first sub-gate 223a and a second sub-gate 223b. The first sub-gate 223a may overlap the first sub-channel 221c1. The second sub-gate 223b may overlap the first sub-channel 221c1, the second sub-channel 221c2 and the third sub-channel 221c3. The second sub-gate 223b may be disposed on a different layer from the first sub-gate 223a. The first sub-gate 223a may be disposed closer to the second semiconductor pattern 221 than the second sub-gate 223b. For example, the first sub-gate 223a may be disposed between the first sub-channel 221c1 and the second sub-gate 223b. The second sub-channel 221c2 and the third sub-channel 221c3 may be disposed outside the first sub-gate 223a. The second sub-gate 223b may be spaced apart from the first sub-gate 223a. For example, a distance between the second sub-channel 221c2 and the second sub-gate 223b and a distance between the third sub-channel 221c3 and the second sub-gate 223b may be greater than a distance between the first sub-channel 221c1 and the first sub-gate 223a.

In a general thin film transistor, a voltage applied to a gate electrode at the moment that a channel is formed in a channel region of a semiconductor pattern is referred to as the threshold voltage. The threshold voltage of the thin film transistor is proportional to the distance between the semiconductor pattern and the gate electrode of the corresponding thin film transistor. That is, in the display apparatus according to the embodiment of the present disclosure, a first threshold voltage applied to the first sub-gate 223a at the moment that a channel is formed in the first sub-channel 221c1 may be lower than a second threshold voltage applied to the second sub-gate 223b at the moment that a channel is formed in the second sub-channel 221c2 and the third sub-channel 221c3. Thus, in the display apparatus according to the embodiment of the present disclosure, a channel of the first sub-channel 221c1 may be formed before a channel of the second sub-channel 221c2 and a channel of the third sub-channel 221c3.

In the display apparatus according to the embodiment of the present disclosure, when a channel is formed in all of the first sub-channel 221c1, the second sub-channel 221c2 and of the third sub-channel 221c3 in each pixel area PA, the second thin film transistor T2 of the corresponding pixel area PA may be turned on. Thus, in the display apparatus according to the embodiment of the present disclosure, if a voltage between the first threshold voltage and the second threshold voltage is applied to the first sub-gate 223a and the second sub-gate 223b of each pixel area PA, a channel may be formed in only the first sub-channel 221c1 of the corresponding pixel area PA, such that the second thin film transistor T2 of the corresponding pixel area PA may not be turned on. That is, in the display apparatus according to the embodiment of the present disclosure, the second thin film transistor T2 of each pixel area PA may be turned on at the moment that a channel is formed in the second sub-channel 221c2 and the third sub-channel 221c3 of the corresponding pixel area PA. Therefore, in the display apparatus according to the embodiment of the present disclosure, a channel formed in the second sub-channel 221c2 and a channel formed in the third sub-channel 221c3 of each pixel area PA may be an effective channel of the second thin film transistor T2 in the corresponding pixel area PA.

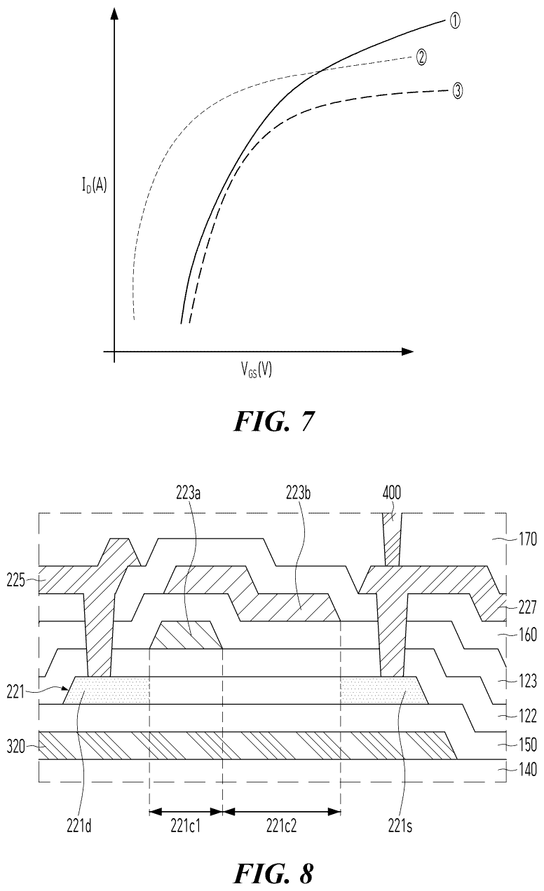

FIG. 7 is a graph showing a driving current according to a voltage applied to a gate electrode in a first example thin film transistor (1) including a channel region in which the first sub-channel 221c1 is disposed between the second sub-channel 221c2 and the third sub-channel 221c3, a second example thin film transistor (2) including only a channel region composed of only the first sub-channel 221c1, and a third example thin film transistor (3) including a channel region composed of only the second sub-channel 221c2 or the third sub-channel 221c3. Here, the channel region of the first example thin film transistor (1), the channel region of the second example thin film transistor (2), and the channel region of the third example thin film transistor (3) may be formed to have a same length and a same width.

Referring to FIG. 7, the maximum driving current of the first example thin film transistor 1 may be larger than the maximum driving current of the second example thin film transistor 2 and the maximum driving current of the third example thin film transistor (3). In generally, the driving current generated by a thin film transistor is inversely proportional to a length in channel of the corresponding thin film transistor. That is, in the display apparatus according to the embodiment of the present disclosure, a channel in the first sub-channel 221c1 of each pixel area PA may be formed before the second thin film transistor T2 of the corresponding pixel area PA is turned on, such that a length of the effective channel generated in the second semiconductor pattern 221 of each pixel area PA may be reduced, and the driving current generated by the second thin film transistor T2 of each pixel area PA may be increased. Therefore, in the display apparatus according to the embodiment of the present disclosure, efficiency of the second thin film transistor T2 in each pixel area PA may be improved.

And, in the display apparatus according to the embodiment of the present disclosure, if a voltage being lower than the first threshold voltage is applied to the second gate electrode 223 of each pixel area PA, a channel may not be formed in the first sub-channel 221c1, the second sub-channel 221c2 and the third sub-channel 221c3 of each pixel area PA. Thus, in the display apparatus according to the embodiment of the present disclosure, occurrence of leakage current in the turn-off state of the second thin film transistor T2 in each pixel area PA and malfunction of the second thin film transistor T2 in each pixel area PA may be prevented by reducing a length of the effective channel formed in the second semiconductor pattern 221 of each pixel area PA. Therefore, in the display apparatus according to the embodiment of the present disclosure, reliability of the pixel driving circuit DC in each pixel may be improved.

Referring to FIGS. 2 to 6, the first sub-gate 223a may be disposed on a same layer as the first gate electrode 213. The first sub-gate 223a may include a same material as the first gate electrode 213. The first sub-gate 223a may be formed by a same process as the first gate electrode 213. For example, the first sub-gate 223a may be formed simultaneously with the first gate electrode 213. The second sub-gate 223b may include a different material from the first sub-gate 223a. For example, the second sub-gate 223b may be disposed on a different layer from the first gate electrode 213.

The second sub-gate 223b may be electrically connected to the first sub-gate 223a. For example, the second gate electrode 223 may include a connection gate 223c electrically connecting the second sub-gate 223b to the first sub-gate 223a. The electrical connection between the first sub-gate 223a and the second sub-gate 223b may be made outside the second semiconductor pattern 221. For example, the connection gate 223c may not overlap the second semiconductor pattern 221. Thus, in the display apparatus according to the embodiment of the present disclosure, a channel by the connection gate 223c may not be formed. The connection gate 223c may be disposed on a different layer from the first sub-gate 223a and the second sub-gate 223b. For example, the connection gate 223c may include a different material from the first sub-gate 223a and the second sub-gate 223b.

The connection gate 223c may be disposed on a same layer as the first drain electrode 215 and the first source electrode 217. The connection gate 223c may include a same material as the first drain electrode 215 and the first source electrode 217. The connection gate 223c may be formed by a same process as the first drain electrode 215 and the first source electrode 217. For example, the connection gate 223c may be formed simultaneously with the first drain electrode 215 and the first source electrode 217. Thus, in the display apparatus according to the embodiment of the present disclosure, decrease in process efficiency due to a process of forming the second gate electrode 223 may be minimized.

The second drain electrode 225 may include a conductive material. For example, the second drain electrode 225 may include a metal, such as aluminum (Al), chrome (Cr), copper (Cu), molybdenum (Mo), titanium (Ti) and tungsten (W). The second drain electrode 225 may include a different material from the first sub-gate 223a and the second sub-gate 223b. The second drain electrode 225 may be disposed on a different layer from the first sub-gate 223a and the second sub-gate 223b. For example, the second drain electrode 225 may be disposed on a same layer as the connection gate 223c. The second drain electrode 225 may include a same material as the connection gate 223c. The second drain electrode 225 may be formed by a same process as the connection gate 223c. For example, the second drain electrode 225 may be formed simultaneously with the connection gate 223c. The second drain electrode 225 may be spaced apart from the connection gate 223c. For example, the second drain electrode 225 may be insulated from the second gate electrode 223. The second drain electrode 225 may be electrically connected to the second drain region 221d of the second semiconductor pattern 221.

The second source electrode 227 may include a conductive material. For example, the second source electrode 227 may include a metal, such as aluminum (Al), chrome (Cr), copper (Cu), molybdenum (Mo), titanium (Ti) and tungsten (W). The second source electrode 227 may include a different material from the first sub-gate 223a and the second sub-gate 223b. The second source electrode 227 may be disposed on a different layer from the first sub-gate 223a and the second sub-gate 223b. For example, the second source electrode 227 may be disposed on a same layer as the second drain electrode 225 and/or the connection gate 223c. The second source electrode 227 may include a same material as the second drain electrode 225 and/or the connection gate 223c. The second source electrode 227 may be formed by a same process as the second drain electrode 225 and/or the connection gate 223c. For example, the second source electrode 227 may be formed simultaneously with the second drain electrode 225 and/or the connection gate 223c. The second source electrode 227 may be spaced apart from the connection gate 223c. For example, the second source electrode 227 may be insulated from the second gate electrode 223. The second source electrode 227 may be electrically connected to the second source region 221s of the second semiconductor pattern 221.

The storage capacitor Cst of each pixel area PA may maintain a signal applied to the second gate electrode 223 of the corresponding pixel area PA for one frame. For example, the storage capacitor Cst of each pixel area PA may be electrically connected between the second gate electrode 223 and the second source electrode 227 of the corresponding pixel area PA. The storage capacitor Cst of each pixel area PA may have a stacked structure of capacitor electrodes 251, 252 and 253. The storage capacitor Cst of each pixel area PA may be formed by using a process of forming the first thin film transistor T1 and the second thin film transistor T2 of the corresponding pixel area PA. For example, the storage capacitor Cst of each pixel area PA may include a first capacitor electrode 251 disposed on a same layer as the first sub-gate 223a, a second capacitor electrode 252 disposed on a same layer as the second sub-gate 223b, and a third capacitor electrode 253 disposed on a same layer as the second source electrode 227. Thus, in the display apparatus according to the embodiment of the present disclosure, a size occupied by the storage capacitor Cst in each pixel area PA may be minimized, without decreasing process efficiency.

The gate driver GD formed on the bezel area BZ may include at least one circuit thin film transistor 290. The circuit thin film transistor 290 may be a switching thin film transistor. For example, the circuit thin film transistor 290 may include a circuit semiconductor pattern 291, a circuit gate electrode 293, a circuit drain electrode 295 and a circuit source electrode 297.

The circuit semiconductor pattern 291 may include a semiconductor material. The circuit semiconductor pattern 291 may be disposed on a different layer from the first semiconductor pattern 211 and the second semiconductor pattern 221 of each pixel area PA. The circuit semiconductor pattern 291 may include a material different from the first semiconductor pattern 211 and the second semiconductor pattern 221 of each pixel area PA. For example, the circuit semiconductor pattern 291 may include amorphous silicon (a-Si) or polycrystalline silicon (poly-Si). The circuit semiconductor pattern 291 may include low-temperature poly-Si (LTPS). The circuit semiconductor pattern 291 may include a circuit drain region, a circuit channel region, and a circuit source region. The circuit channel region may be disposed between the circuit drain region and the circuit source region. The circuit drain region and the circuit source region may have a lower resistance than the circuit channel region. For example, the circuit drain region and the circuit source region may include conductive impurities. The circuit channel region may be a region, which is not doped with conductive impurities.

The circuit gate electrode 293 may be disposed on a portion of the circuit semiconductor pattern 291. For example, the circuit gate electrode 293 may overlap the circuit channel region of the circuit semiconductor pattern 291. The circuit drain region and the circuit source region of the circuit semiconductor pattern 291 may be disposed outside the circuit gate electrode 293. The circuit gate electrode 293 may include a conductive material. For example, the circuit gate electrode 293 may include a metal, such as aluminum (Al), chrome (Cr), copper (Cu), molybdenum (Mo), titanium (Ti) and tungsten (W). The circuit gate electrode 293 may be insulated from the circuit semiconductor pattern 291. For example, the circuit drain region of the circuit semiconductor pattern 291 may be electrically connected to the circuit source region of the circuit semiconductor pattern 291 according to a voltage applied to the circuit gate electrode 293.

The circuit gate electrode 293 may be disposed on a different layer from the first gate electrode 213 and the second gate electrode 223 of each pixel area PA. The circuit gate electrode 293 may include a different material from the first gate electrode 213, the first sub-gate 223a, the second sub-gate 223b and the connection gate 223c of each pixel area PA.

The circuit drain electrode 295 may include a conductive material. For example, the circuit drain electrode 295 may include a metal, such as aluminum (Al), chrome (Cr), copper (Cu), molybdenum (Mo), titanium (Ti) and tungsten (W). The circuit drain electrode 295 may include a different material from the circuit gate electrode 293. The circuit drain electrode 295 may be disposed on a different layer from the circuit gate electrode 293. For example, the circuit drain electrode 295 may be insulated from the circuit gate electrode 293. The circuit drain electrode 295 may be disposed on a same layer as the first drain electrode 215 of each pixel area PA. The circuit drain electrode 295 may include a same material as the first drain electrode 215 of each pixel area PA. The circuit drain electrode 295 may be formed by a same process as the first drain electrode 215 of each pixel area PA. For example, the circuit drain electrode 295 may be formed simultaneously with the first drain electrode 215 of each pixel area PA. The circuit drain electrode 295 may be electrically connected to the circuit drain region of the circuit semiconductor pattern 291.

The circuit source electrode 297 may include a conductive material. For example, the circuit source electrode 297 may include a metal, such as aluminum (Al), chrome (Cr), copper (Cu), molybdenum (Mo), titanium (Ti) and tungsten (W). The circuit source electrode 297 may include a different material from the circuit gate electrode 293. The circuit source electrode 297 may be disposed on a different layer from the circuit gate electrode 293. For example, the circuit source electrode 297 may be insulated from the circuit gate electrode 293. The circuit source electrode 297 may be disposed on a same layer as the circuit drain electrode 295. The circuit source electrode 297 may include a same material as the circuit drain electrode 295. The circuit source electrode 297 may be formed by a same process as the circuit drain electrode 295. For example, the circuit source electrode 297 may be formed simultaneously with the circuit drain electrode 295. The circuit source electrode 297 may be spaced apart from the circuit drain electrode 295. The circuit source electrode 297 may be electrically connected to the circuit source region of the circuit semiconductor pattern 291.

The pixel driving circuit DC of each pixel area PA and the circuit thin film transistor 290 may be disposed on a device substrate 100. For example, the pixel driving circuit DC of each pixel area PA and the circuit thin film transistor 290 may be supported by the device substrate 100. The device substrate 100 may include an insulating material. For example, the device substrate 100 may include glass or plastic. A plurality of insulating layers 110, 121, 122, 123, 130, 140, 150, 160, 170, 180 and 190 for preventing unnecessary electrical connection in each pixel area PA and the gate driver GD may be disposed on the device substrate 100. For example, a lower buffer layer 110, a first gate insulating layer 121, a second gate insulating layer 122, a third gate insulating layer 123, a lower interlayer insulating layer 130, a separation insulating layer 140, an upper buffer layer 150, an upper interlayer insulating layer 160, a lower planarization layer 170, an upper planarization layer 180 and a bank insulating layer 190 may be disposed on the device substrate 100.

The lower buffer layer 110 may be disposed close to the device substrate 100. The lower buffer layer 110 may prevent pollution due to the device substrate 100 in a process of forming the pixel driving circuit DC of each pixel area PA and the circuit thin film transistor 290. For example, an upper surface of the device substrate 100 toward the pixel driving circuit DC of each pixel area PA and the circuit thin film transistor 290 may be completely covered by the lower buffer layer 110. The lower buffer layer 110 may be in direct contact with the upper surface of the device substrate 100. The pixel driving circuit DC of each pixel area PA and the circuit thin film transistor 290 may be disposed on the lower buffer layer 110. The lower buffer layer 110 may include an insulating material. For example, the lower buffer layer 110 may include an inorganic insulating material, such as silicon oxide (SiOx) and silicon nitride (SiNx). The lower buffer layer 110 may have a multi-layer structure.

The first gate insulating layer 121 may be disposed on the lower buffer layer 110. The circuit gate electrode 293 may be insulated from the circuit semiconductor pattern 291 by the first gate insulating layer 121. For example, the circuit semiconductor pattern 291 may be covered by the first gate insulating layer 121. The circuit gate electrode 293 may be disposed on the first gate insulating layer 121. The first gate insulating layer 120 may include an insulating material. For example, the first gate insulating layer 121 may include an inorganic insulating material, such as silicon oxide (SiOx) and silicon nitride (SiNx).

The lower interlayer insulating layer 130 may be disposed on the first gate insulating layer 121. The circuit drain electrode 295 and the circuit source electrode 297 may be insulated from the circuit gate electrode 293 by the lower interlayer insulating layer 130. For example, the circuit gate electrode 293 may be covered by the lower interlayer insulating layer 130. The circuit drain electrode 295 and the circuit source electrode 297 may be disposed on the lower interlayer insulating layer 130. The lower interlayer insulating layer 130 may include an insulating material. For example, the lower interlayer insulating layer 130 may include an inorganic insulating material, such as silicon oxide (SiOx) and silicon nitride (SiNx).

A first light-blocking pattern 310 may be disposed between the first gate insulating layer 121 and the lower interlayer insulating layer 130 of each pixel area PA. The first light-blocking pattern 310 of each pixel area PA may include a material absorbing or reflecting light. For example, the first light-blocking pattern 310 of each pixel area PA may include a metal. The first light-blocking pattern 310 of each pixel area PA may be disposed on a same layer as the circuit gate electrode 293. The first light-blocking pattern 310 of each pixel area PA may include a same material as the circuit gate electrode 293. The first light-blocking pattern 310 of each pixel area PA may be formed by a same process as the circuit gate electrode 293. For example, the first light-blocking pattern 310 of each pixel area PA may be formed simultaneously with the circuit gate electrode 293. The first light-blocking pattern 310 of each pixel area PA may overlap the first semiconductor pattern 211 of the corresponding pixel area PA. For example, light traveling toward the first semiconductor pattern 211 of each pixel area PA by passing through the device substrate 100 may be blocked by the first light-blocking pattern 310 of the corresponding pixel area PA. Thus, in the display apparatus according to the embodiment of the present disclosure, change in characteristics of the first thin film transistor T1 in each pixel area PA due to external light introduced through the device substrate 100 may be prevented.

A specific voltage may be applied to the first light-blocking pattern 310 of each pixel area PA. For example, the first light-blocking pattern 310 of each pixel area PA may be electrically connected to the first gate electrode 213 of the corresponding pixel area PA. Thus, in the display apparatus according to the embodiment of the present disclosure, the first light-blocking pattern 310 of each pixel area PA may function as a gate electrode of the first thin film transistor T1 in the corresponding pixel area PA. Therefore, in the display apparatus according to the embodiment of the present disclosure, response speed of the first thin film transistor T1 in each pixel area PA may be increased.

The separation insulating layer 140 may be disposed on the lower interlayer insulating layer 130. The separation insulating layer 140 may prevent the deterioration and the damage of the circuit semiconductor pattern 291 due to a process of forming the pixel driving circuit DC in each pixel area PA. For example, the first thin film transistor T1, the second thin film transistor T2 and the storage capacitor Cst of each pixel area PA may be disposed on the separation insulating layer 140. The separation insulating layer 140 may include an insulating material. For example, the separation insulating layer 140 may be an inorganic insulating material, such as silicon oxide (SiOx) and silicon nitride (SiNx). The separation insulating layer 140 may have a greater thickness than the lower interlayer insulating layer 130. The separation insulating layer 140 may have a multi-layer structure. For example, the separation insulating layer 140 may have a stacked structure of an inorganic insulating layer being made of silicon oxide (SiOx) and an inorganic insulating layer being made of silicon nitride (SiNx).

The upper buffer layer 150 may be disposed on the separation insulating layer 140. The upper buffer layer 150 may prevent pollution due to the circuit semiconductor pattern 291, the circuit gate electrode 293 and the first light-blocking pattern 310 of each pixel area PA in a process of forming the first semiconductor pattern 211 and the second semiconductor pattern 221 of each pixel area PA. For example, the first semiconductor pattern 211 and the second semiconductor pattern 221 of each pixel area PA may be disposed on the upper buffer layer 150. The upper buffer layer 150 may include an insulating material. For example, the upper buffer layer 150 may include an inorganic insulating material, such as silicon oxide (SiOx) and silicon nitride (SiNx).

A second light-blocking pattern 320 may be disposed between the separation insulating layer 140 and the upper buffer layer 150 of each pixel area PA. The second light-blocking pattern 320 of each pixel area PA may include a material absorbing or reflecting light. For example, the second light-blocking pattern 320 of each pixel area PA may include a metal. The second light-blocking pattern 320 of each pixel area PA may overlap the second semiconductor pattern 221 of the corresponding pixel area PA. For example, light traveling toward the second semiconductor pattern 221 of each pixel area PA by passing through the device substrate 100 may be blocked by the second light-blocking pattern 320 of the corresponding pixel area PA. Thus, in the display apparatus according to the embodiment of the present disclosure, change in the characteristics of the second thin film transistor T2 in each pixel area PA due to the external light introduced through the device substrate 100 may be prevented.

A specific voltage may be applied to the second light-blocking pattern 320 of each pixel area PA. For example, the second light-blocking pattern 320 of each pixel area PA may be electrically connected to the second drain electrode 225 of the corresponding pixel area PA. Thus, in the display apparatus according to the embodiment of the present disclosure, change in the characteristics of the second thin film transistor T2 in each pixel area PA due to the external light may be effectively prevented.

A distance between the second light-blocking pattern 320 and the second semiconductor pattern 221 in each pixel area PA may be smaller than a distance between the first light-blocking pattern 310 and the first semiconductor pattern 211 in the corresponding pixel area PA. Generally, the amount of change in the effective gate voltage of a thin film transistor on a conductive pattern may be determined by the following equation. Here, ΔV_{eff} represents the amount of change in the effective gate voltage, ΔV_{GAT} represents the amount of change in a voltage applied to the gate electrode, C₁ represents capacitance of the parasitic capacitor formed between the conductive pattern and a semiconductor pattern of the corresponding thin film transistor, C₂ represents capacitance of the parasitic capacitor formed between the semiconductor pattern and the gate electrode of the corresponding thin film transistor, and C_{ACT} represents capacitance of the parasitic capacitor formed by a voltage applied to a source region and a drain region of the corresponding thin film transistor.

$$Δ {V}_{eff} = \frac{C 2}{C 2 + {C}_{ACT} + C 1} \times Δ {V}_{GAT} \qquad Equation$$

Capacitance of a capacitor is inversely proportional to a distance between conductors constituting the corresponding capacitor. In the display apparatus according to the embodiment of the present disclosure, the capacitance of the parasitic capacitor formed between the second light-blocking pattern 320 and the second semiconductor pattern 221 of each pixel area PA may be larger than the capacitance of the parasitic capacitor formed between the first light-blocking pattern 310 and the first semiconductor pattern 211 of the corresponding pixel area PA. Thus, in the display apparatus according to the embodiment of the present disclosure, the amount of change in the effective gate voltage of the second thin film transistor T2 in each pixel area PA may be smaller than the amount of change in the effective gate voltage of the first thin film transistor T1 in the corresponding pixel area PA. In a general thin film transistor, when the amount of change in the effective gate voltage is reduced, the amount of change in a current according to change in a voltage applied to the gate electrode of the corresponding thin film transistor may be decreased, and S-factor of the corresponding thin film transistor may be increased. Here, the S-factor of the thin film transistor means an inverse ratio of the amount of change in the current generated by the corresponding thin film transistor and the amount of change in the voltage applied to the gate electrode of the corresponding thin film transistor. That is, in the display apparatus according to the embodiment of the present disclosure, the S-factor of the second thin film transistor T2 in each pixel area PA may be relatively increased, such that the amount of change in the driving current generated by the corresponding pixel area PA according to change in the voltage applied to the second gate electrode 223 of the corresponding pixel area PA may be reduced. Therefore, in the display apparatus according to the embodiment of the present disclosure, occurrence of stains may be prevented when a low gray-scale image may be realized.

The second gate insulating layer 122 may be disposed on the upper buffer layer 150. The first gate electrode 213 and the first sub-gate 223a of each pixel area PA may be insulated from the first semiconductor pattern 211 and the second semiconductor pattern 221 of the corresponding pixel area PA by the second gate insulating layer 122. For example, the first semiconductor pattern 211 and the second semiconductor pattern 221 of each pixel area PA may be covered by the second gate insulating layer 122. The first gate electrode 213 and the first sub-gate 223a of each pixel area PA may be disposed on the second gate insulating layer 122. The second gate insulating layer 122 may include an insulating material. For example, the second gate insulating layer 122 may be an inorganic insulating material, such as silicon oxide (SiOx) and silicon nitride (SiNx).

The third gate insulating layer 123 may be disposed on the second gate insulating layer 122. The second sub-gate 223b of each pixel area PA may be spaced apart from the first sub-gate 223a of the corresponding pixel area PA by the third gate insulating layer 123. For example, the first gate electrode 213 and the first sub-gate 223a of each pixel area PA may be covered by the third gate insulating layer 123. The second sub-gate 223b of each pixel area PA may be disposed on the third gate insulating layer 123. The second capacitor electrode 252 of each pixel area PA may be spaced apart from the first capacitor electrode 251 of the corresponding pixel area PA. For example, the third gate insulating layer 123 may extend between the first capacitor electrode 251 and the second capacitor electrode 252 of each pixel area PA. The third gate insulating layer 123 may include an insulating material. For example, the third gate insulating layer 123 may include an inorganic insulating material, such as silicon oxide (SiOx) and silicon nitride (SiNx). The third gate insulating layer 123 may include a same material as the second gate insulating layer 122. For example, an interface between the second gate insulating layer 122 and the third gate insulating layer 123 may not be recognized.

In each pixel area PA, only the second gate insulating layer 122 may be disposed between the first sub-channel 221c1 and the first sub-gate 223a, and the second gate insulating layer 122 and the third gate insulating layer 123 may be disposed between the second sub-channel 221c2 and the second sub-gate 223b of each pixel area PA and between the third sub-channel 221c3 and the second sub-gate 223b of each pixel area PA. The second gate insulating layer 122 may be in direct contact with the first semiconductor pattern 211, the first gate electrode 213, the second semiconductor pattern 221 and the first sub-gate 223a. For example, the capacitance of the parasitic capacitor formed between the first semiconductor pattern 211 and the first gate electrode 213 of each pixel area PA may be a same as the capacitance of the parasitic capacitor formed between the second semiconductor pattern and the first sub-gate 223a of the corresponding pixel area PA. Thus, in the display apparatus according to the embodiment of the present disclosure, the second thin film transistor T2 of each pixel area PA may have a relative large S-factor due to the location of the second light-blocking pattern 320 and the location of the second sub-gate 223b in each pixel area PA. That is, in the display apparatus according to the embodiment of the present disclosure, a difference in S-factor between the first thin film transistor T1 and the second thin film transistor T2 in each pixel area PA may be determined by the location of the second light-blocking pattern 320 and the location of the second sub-gate 223b in the corresponding pixel area PA. For example, in the display apparatus according to the embodiment of the present disclosure, a relative S-factor of the second thin film transistor T2 in each pixel PA may be adjusted. Therefore, in the display apparatus according to the embodiment of the present disclosure, relative characteristics of the second thin film transistors T2 in each pixel area PA may be effectively controlled.

The upper interlayer insulating layer 160 may be disposed on the third gate insulating layer 123. The second sub-gate 223b of each pixel area PA may be covered by the upper interlayer insulating layer 160. The first drain electrode 215, the first source electrode 217, the second drain electrode 225 and the second source electrode 227 of each pixel area PA may be disposed on the upper interlayer insulating layer 160. The upper interlayer insulating layer 160 may include an insulating material. For example, the upper interlayer insulating layer 160 may include an inorganic insulating material, such as silicon oxide (SiOx) and silicon nitride (SiNx). The first drain electrode 215 and the first source electrode 217 of each pixel area PA may be insulated from the first gate electrode 213 of the corresponding pixel area PA by the third gate insulating layer 123 and the upper interlayer insulating layer 160. The second drain electrode 225 and the second source electrode 227 of each pixel area PA may be insulated from the first sub-gate 223a and the second sub-gate 223b of the corresponding pixel area PA by the third gate insulating layer 123 and the upper interlayer insulating layer 160.

The first drain electrode 215 of each pixel area PA may be electrically connected to the first drain region of the first semiconductor pattern 211 in the corresponding pixel area PA by passing through the second gate insulating layer 122, the third gate insulating layer 123 and the upper interlayer insulating layer 160, and the first source electrode 217 of each pixel area PA may be electrically connected to the first source region of the first semiconductor pattern 211 in the corresponding pixel area PA by passing through the second gate insulating layer 122, the third gate insulating layer 123 and the upper interlayer insulating layer 160. The second drain electrode 225 of each pixel area PA may be electrically connected to the second drain region 221d of the second semiconductor pattern 221 in the corresponding pixel area PA by passing through the second gate insulating layer 122, the third gate insulating layer 123 and the upper interlayer insulating layer 160, and the second source electrode 227 of each pixel area PA may be electrically connected to the second source region 221s of the second semiconductor pattern 221 in the corresponding pixel area PA by passing through the second gate insulating layer 122, the third gate insulating layer 123 and the upper interlayer insulating layer 160. The connection gate 223c of each pixel area PA may be electrically connected to the first sub-gate 223a of the corresponding pixel area PA by passing through the third gate insulating layer 123 and the upper interlayer insulating layer 160 of the corresponding pixel area PA, and to the second sub-gate 223b of the corresponding pixel area PA by passing through the upper interlayer insulating layer 160 of the corresponding pixel area PA. A contact hole to connect between the connection gate 223c and the first sub-gate 223a and a contact hole to connect between the connection gate 223c and the second sub-gate 223b in each pixel area PA may be formed simultaneously with a contact hole to connect between the first drain electrode 215 and the first drain region, a contact hole to connect between the first source electrode 217 and the first source region, a contact hole to connect between the second drain electrode 225 and the second drain region 221d, and a contact hole to connect to between the second source electrode 227 and the second source region 221s. Thus, in the display apparatus according to the embodiment of the present disclosure, decreasing efficiency in a process due to a process of forming the second gate electrode 223 of each pixel area PA may be minimized.

The third capacitor electrode 253 of each pixel area PA may be spaced apart from the second capacitor electrode 252 of the corresponding pixel area PA by the upper interlayer insulating layer 160. For example, the upper interlayer insulating layer 160 may extend between the second capacitor electrode 252 and the third capacitor electrode 253. The circuit drain electrode 295 and the circuit source electrode 297 may be disposed on the upper interlayer insulating layer 160. For example, the circuit drain electrode 295 may be electrically connected to the circuit drain region by passing through the first gate insulating layer 121, the lower interlayer insulating layer 130, the separation insulating layer 140, the upper buffer layer 150, the second gate insulating layer 122, the third insulating layer 123 and the upper interlayer insulating layer 160, and the circuit source electrode 297 may be electrically connected to the circuit source region by passing through the first gate insulating layer 121, the lower interlayer insulating layer 130, the separation insulating layer 140, the upper buffer layer 150, the second gate insulating layer 122, the third insulating layer 123 and the upper interlayer insulating layer 160.

The lower planarization layer 170 may be disposed on the upper interlayer insulating layer 160. The upper planarization layer 180 may be disposed on the lower planarization layer 170. The lower planarization layer 170 and the upper planarization layer 180 may remove a thickness difference due to the pixel driving circuit DC of each pixel area PA. For example, an upper surface of the upper planarization layer 180 opposite to the device substrate 100 may be a flat surface. The first drain electrode 215, the first source electrode 217, the second drain electrode 225, the second source electrode 227, the connection gate 223c and the third capacitor electrode 253 of each pixel area PA may be covered by the lower planarization layer 170. The lower planarization layer 170 and the upper planarization layer 180 may extend onto the bezel area BZ of the device substrate 100. For example, the lower planarization layer 170 and the upper planarization layer 180 may be stacked on the circuit drain electrode 295 and the circuit source electrode 297. A thickness difference due to the circuit thin film transistor 290 may be removed by the lower planarization layer 170 and the upper planarization layer 180.

The lower planarization layer 170 and the upper planarization layer 180 may include an insulating material. The lower planarization layer 170 and the upper planarization layer 180 may include a different material from the upper interlayer insulating layer 160. The lower planarization layer 170 and the upper planarization layer 180 may have a material having a relative high fluidity. For example, the lower planarization layer 170 and the upper planarization layer 180 may include an organic insulating material. The upper planarization layer 180 may include a same material as the lower planarization layer 170. For example, an interface between the lower planarization layer 170 and the upper planarization layer 180 may not be recognized.

The light-emitting device 500 of each pixel area PA may be disposed on the upper planarization layer 180 of the corresponding pixel area PA. The light-emitting device 500 of each pixel area PA may emit light displaying a specific color. For example, the light-emitting device 500 of each pixel area PA may include a first electrode 510, a light-emitting unit 520 and a second electrode 530, which are sequentially stacked on the upper planarization layer 180 of the corresponding pixel area PA.

The first electrode 510 may include a conductive material. The first electrode 510 may include a material having a high reflectance. For example, the first electrode 510 may include a metal, such as aluminum (Al) or silver (Ag). The first electrode 510 may have a multi-layer structure. For example, the first electrode 510 may have a structure in which a reflective electrode made of a metal is disposed between transparent electrodes made of a transparent conductive material, such as ITO and IZO.

The light-emitting unit 520 may generate light having luminance corresponding to a voltage difference between the first electrode 510 and the second electrode 530. For example, the light-emitting unit 520 may include at least one emission material layer (EML). The emission material layer may include an emission material. The emission material may include an organic material, an inorganic material, or a hybrid material. For example, the display apparatus according to the embodiment of the present disclosure may be an organic light-emitting display apparatus including an organic emission material.

The light-emitting unit 520 may include at least one functional layer for smooth supply of holes or electrons. For example, the light-emitting unit 520 may include at least one of a hole injection layer (HIL), a hole transport layer (HTL), an electron transport layer (ETL) and an electron injection layer (EIL). Thus, in the display apparatus according to the embodiment of the present disclosure, efficiency of the light-emitting unit 520 may be improved.

The second electrode 530 may include a conductive material. The second electrode 530 may include a different material from the first electrode 510. A transmittance of the second electrode 530 may be higher than a transmittance of the first electrode 510. For example, the second electrode 530 may be a transparent electrode made of a transparent conductive material, such as ITO and IZO, or a translucent electrode in which metals such as Ag and Mg are thinly formed. Thus, in the display apparatus according to the embodiment of the present disclosure, light generated by the light-emitting unit 520 may be emitted outside through the second electrode 530.

The light-emitting device 500 of each pixel area PA may be electrically connected to the second thin film transistor T2 of the corresponding pixel area PA. For example, the first electrode 510 of each pixel area PA may be electrically connected to the second source electrode 227 of the corresponding pixel area PA. The first electrode 510 of each pixel area PA may include a portion being in direct contact with the upper surface of the upper planarization layer 180 on the corresponding pixel area PA. The light-emitting unit 520 and the second electrode 530 of each pixel area PA may be stacked on a portion of the corresponding first electrode 510, which is in direct contact with the upper surface of the upper planarization layer 180. Thus, in the display apparatus according to the embodiment of the present disclosure, deviation in the luminance according to the generating location of the light, which is emitted from the light-emitting device 500 of each pixel area PA may be prevented.

An intermediate electrode 400 electrically connecting the first electrode 510 of each pixel area PA to the second source electrode 227 of the corresponding pixel area PA may be disposed between the lower planarization layer 170 and the upper planarization layer 180 of the corresponding pixel area PA. The intermediate electrode 400 of each pixel area PA may include a conductive material. The intermediate electrode 400 of each pixel area PA may include a material having a relative low resistance. For example, the intermediate electrode 400 of each pixel area PA may include a metal. The intermediate electrode 400 of each pixel area PA may be in direct contact with the second source electrode 227 and the first electrode 510 of the corresponding pixel area PA. For example, the intermediate electrode 400 of each pixel area PA may be in contact with the second source electrode 227 of the corresponding pixel area PA by passing through the lower planarization layer 170, and the first electrode 510 of each pixel area PA may be in contact with the intermediate electrode 400 of the corresponding pixel area PA by passing through the upper planarization layer 180. Thus, in the display apparatus according to the embodiment of the present disclosure, the first electrode 510 of each pixel area PA may be stably connected to the second source electrode 227 of the corresponding pixel area PA. Therefore, in the display apparatus according to the embodiment of the present disclosure, reliability of electrical connections between the pixel driving circuit DC and the light-emitting device 500 in each pixel area PA may be improved.

The bank insulating layer 190 may be disposed on the upper planarization layer 180. The bank insulating layer 190 may surround an emission area in each pixel area PA. For example, the bank insulating layer 190 may partially expose the first electrode 510 of each pixel area PA. A portion of each first electrode 510 exposed by the bank insulating layer 190 may be a region being in direct contact with the upper surface of the upper planarization layer 180. For example, the light-emitting unit 520 and the second electrode 530 of each pixel area PA may be stacked on a portion of the corresponding first electrode 510 exposed by the bank insulating layer 190. An edge of the first electrode 510 in each pixel area PA may be covered by the bank insulating layer 190. For example, the first electrode 510 of each pixel area PA may be insulated from the first electrode 510 of adjacent pixel area PA by the bank insulating layer 190. The bank insulating layer 190 may include an insulating material. For example, the bank insulating layer 190 may include an organic insulating material. The bank insulating layer 190 may include a different material from the upper planarization layer 180.

The light emitted from the light-emitting device 500 of each pixel area PA may display a different color from the light emitted from the light-emitting device 500 of adjacent pixel area PA. For example, the light-emitting unit 520 of each pixel area PA may be spaced apart from the light-emitting unit 520 of adjacent pixel area PA. The light-emitting unit 520 of each pixel area PA may include an end on the bank insulating layer 190.

A voltage applied to the second electrode 530 of each pixel area PA may be a same as a voltage applied to the second electrode 530 of adjacent pixel area PA. For example, the second electrode 530 of each pixel area PA may be electrically connected to the second electrode 530 of adjacent pixel area PA. The second electrode 530 of each pixel area PA may include a same material as the second electrode 530 of adjacent pixel area PA. The second electrode 530 of each pixel area PA may be formed by a same process as the second electrode 530 of adjacent pixel area PA. For example, the second electrode 530 of each pixel area PA may be formed simultaneously with the second electrode 530 of adjacent pixel area PA. The second electrode 530 of each pixel area PA may be in direct contact with the second electrode 530 of adjacent pixel area PA. For example, the second electrode 530 of each pixel area PA may extend onto the bank insulating layer 160. Thus, in the display apparatus according to the embodiment of the present disclosure, a process of forming the second electrode 530 in each pixel area PA may be simplified. And, in the display apparatus according to the embodiment of the present disclosure, the luminance of the light generated by the light-emitting device 500 in each pixel area PA may be adjusted by the data signal applied to the pixel driving circuit DC in the corresponding pixel area PA.

An encapsulation unit 600 may be disposed on the light-emitting device 500 of each pixel area PA. The encapsulation unit 600 may prevent damage of the light-emitting devices 500 due to external moisture and impact. The encapsulation unit 600 may have a multi-layer structure. For example, the encapsulation unit 600 may include a first encapsulating layer 610, a second encapsulating layer 620 and a third encapsulating layer 630, which are sequentially stacked. The first encapsulating layer 610, the second encapsulating layer 620 and the third encapsulating layer 630 may include an insulating material. The second encapsulating layer 620 may include a different material from the first encapsulating layer 610 and the third encapsulating layer 630. For example, the first encapsulating layer 610 and the third encapsulating layer 630 may include an inorganic insulating material, such as silicon oxide (SiOx) and silicon nitride (SiNx), and the second encapsulating layer 620 may include an organic insulating material. A thickness difference due to the light-emitting device 500 of each pixel area PA may be removed by the second encapsulating layer 620. For example, an upper surface of the encapsulation unit 600 opposite to the device substrate 100 may be a flat surface. Thus, in the display apparatus according to the embodiment of the present disclosure, damage of the light-emitting device 500 in each pixel area PA due to the external moisture and impact may be effectively prevented.

Accordingly, the display apparatus according to the embodiment of the present disclosure may include the light-emitting device 500 and the pixel driving circuit DC in each pixel area PA, wherein the pixel driving circuit DC may include the second thin film transistor T2 electrically connected to the light-emitting device 500, wherein the second semiconductor pattern 221 of the second thin film transistor T2 may include the first sub-channel 221c1, the second sub-channel 221c2 and the third sub-channel 221c3, which are disposed parallel to each other between the second drain region 221d and the second source region 221s, wherein the first sub-channel 221c1 may be disposed between the second sub-channel 221c2 and the third sub-channel 221c3, and wherein the second gate electrode 223 of the second thin film transistor T2 may include the second sub-gate 223b overlapping with the first sub-channel 221c1, the second sub-channel 221c2 and the third sub-channel 221c3, and the first sub-gate 223a disposed between the first sub-channel 221c1 and the second sub-gate 223b. Thus, in the display apparatus according to the embodiment of the present disclosure, a length in the effective channel of the second thin film transistor T2 of each pixel area PA may be reduced by the first sub-gate 223a of the corresponding pixel area PA, and the driving current generated by the second thin film transistor T2 in each pixel area PA may be increased. And, in the display apparatus according to the embodiment of the present disclosure, the S-factor of the second thin film transistor T2 in each pixel area PA may be increased by the second sub-gate 223b of the corresponding pixel area PA. Therefore, in the display apparatus according to the embodiment of the present disclosure, occurrence of stain may be prevented when a low gray-scale image is realized, and efficiency of the second thin film transistor T2 of each pixel driving circuit DC may be improved.

The display apparatus according to the embodiment of the present disclosure is described that the pixel driving circuit DC of each pixel area PA may consist of the first thin film transistor T1, the second thin film transistor T2 and the storage capacitor Cst. However, in the display apparatus according to another embodiment of the present disclosure, the pixel driving circuit DC of each pixel area PA may include at least one thin film transistor. For example, in the display apparatus according to another embodiment of the present disclosure, the pixel driving circuit DC of each pixel area PA may include the first thin film transistor T1, the second thin film transistor T2, the storage capacitor Cst and a third thin film transistor. The third thin film transistor of each pixel area PA may initialize the storage capacitor Cst of the corresponding pixel area PA according to the gate signal. For example, the third thin film transistor of each pixel area PA may include a third gate electrode electrically connected to the corresponding gate line GL, a third drain electrode electrically connected to an initial line applying an initial signal, and a third source electrode electrically connected to the corresponding storage capacitor Cst. Thus, in the display apparatus according to another embodiment of the present disclosure, the degree of freedom in configuration of each pixel driving circuit DC may be improved.

In the display apparatus according to the embodiment of the present disclosure, the location and the electric connection of the first drain electrode 215, the first source electrode 217, the second drain electrodes 225 and the second source electrode 227 in each pixel driving circuit DC may vary depending on the configuration of the corresponding pixel driving circuit DC and/or the type of the corresponding thin film transistors T1 and T2. For example, in the display apparatus according to another embodiment of the present disclosure, the second gate electrode 223 of each pixel driving circuit DC may be electrically connected to the first drain electrode 215 of the corresponding pixel driving circuit DC. Thus, in the display apparatus according to another embodiment of the present disclosure, the degree of freedom in the configuration of each pixel driving circuit DC and the type of each thin film transistor T1 and T2 may be improved.

The display apparatus according to the embodiment of the present disclosure is described that the first semiconductor pattern 211 and the second semiconductor pattern 221 of each pixel area PA may be made of an oxide semiconductor. However, in the display apparatus according to another embodiment of the present disclosure, the second semiconductor pattern 221 of each pixel area PA may include a different material from the first semiconductor pattern 211 of the corresponding pixel area PA. For example, in the display apparatus according to another embodiment of the present disclosure, the first semiconductor pattern 211 of each pixel area PA may include amorphous silicon (a-Si) or polycrystalline silicon (poly-Si). The first thin film transistor T1 of each pixel area PA may be formed to have a same structure as the circuit thin film transistor 290. For example, the first semiconductor pattern 211 of each pixel area PA may be disposed between the lower buffer layer 110 and the first gate insulating layer 121, and the first gate electrode 213 of each pixel area PA may be disposed between the first gate insulating layer 121 and the lower interlayer insulating layer 130. In the display apparatus according to another embodiment of the present disclosure, the first light-blocking pattern 310 of each pixel area PA may not be formed. Thus, in the display apparatus according to another embodiment of the present disclosure, the degree of freedom in the configuration of each pixel driving circuit DC and the type of each thin film transistor T1 and T2 may be improved.

The display apparatus according to the embodiment of the present disclosure is described that the second sub-channel 221c2 and the third sub-channel 221c3 may have a same resistance as the first sub-channel 221c1. However, in the display apparatus according to another embodiment of the present disclosure, the amount of oxygen contained in the second sub-channel 221c2 and the amount of oxygen contained in the third sub-channel 221c3 may be different from the amount of oxygen contained in the first sub-channel 221c1. For example, in the display apparatus according to another embodiment of the present disclosure, the second sub-channel 221c2 may have a resistance between the second drain region 221d and the first sub-channel 221c1, and the third sub-channel 221c3 may have a resistance between the first sub-channel 221c1 and the second source region 221s. Thus, in the display apparatus according to another embodiment of the present disclosure, deterioration in electrical characteristics due to hot carrier effect between the second drain region 221d and the first sub-channel 221c1 and between the first sub-channel 221c1 and the second source region 221s may be prevented.

The display apparatus according to the embodiment of the present disclosure is described that the second channel region 221c of the second semiconductor pattern 221 may include the first sub-channel 221c1, the second sub-channel 221c2 and the third sub-channel 221c3. However, in the display apparatus according to another embodiment of the present disclosure, the second channel region 221c of the second semiconductor pattern 221 may be composed of at least two sub-channels. For example, in the display apparatus according to another embodiment of the present disclosure, the second semiconductor pattern 221 may include a first sub-channel 221c1 between the second drain region 221d and the second source region 221s, and a second sub-channel 221c2 between the first sub-channel 221c1 and the second source region 221s, as shown in FIG. 8. The first sub-gate 223a may be disposed between the first sub-channel 221c1 and the second sub-gate 223b. The second sub-gate 223b may extend on the second sub-channel 221c2. The second sub-gate 223b may be disposed on a different layer from the first sub-gate 223a. A distance between the second sub-channel 221c2 and the second sub-gate 223b may be greater than a distance the first sub-channel 221c1 and the first sub-gate 223a. For example, only the second gate insulating layer 122 may be disposed between the first sub-channel 221c1 and the first sub-gate 223a, and the second gate insulating layer 122 and the third gate insulating layer 123 may be stacked between the second sub-channel 221c2 and the second sub-gate 223b. Thus, in the display apparatus according to another embodiment of the present disclosure, a channel formed in the second sub-channel 221c2 of each pixel area may function as an effective channel of the second thin film transistor in the corresponding pixel area. Therefore, in the display apparatus according to another embodiment of the present disclosure, electrical characteristics of the second thin film transistor in each pixel area may be adjusted by an area ratio of the first sub-channel 221c1 and the second sub-channel 221c2 of the corresponding pixel area. That is, in the display apparatus according to another embodiment of the present disclosure, the driving current generated by the pixel driving circuit of each pixel area may be effectively controlled.

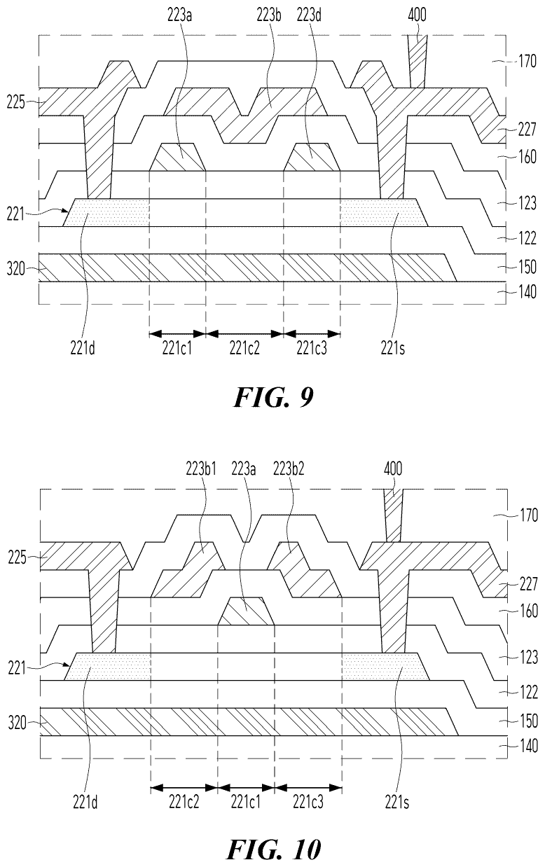

The display apparatus according to the embodiment of the present disclosure is described that the first sub-channel 221c1 in which a channel is formed by the first sub-gate 223a may be disposed between the second sub-channel 221c2 and the third sub-channel 221c3, which include a channel formed by the second sub-gate 223b. However, in the display apparatus according to another embodiment of the present disclosure, the second gate electrode may include a third sub-gate 223d between the third sub-channel 221c3 and the second sub-gate 223b, as shown in FIG. 9. That is, in the display apparatus according to another embodiment of the present disclosure, a channel of the third sub-channel 221c3 may be formed according to a voltage applied to the third sub-gate 223d.

The third sub-gate 223d may be disposed on a same layer as the first sub-gate 223a. For example, the third sub-gate 223d may be disposed between the second gate insulating layer 122 and the third gate insulating layer 123. The third sub-gate 223d may include a same material as the first sub-gate 223a. The third sub-gate 223d may be formed by a same process as the first sub-gate 223a. For example, the third sub-gate 223d may be formed simultaneously with the first sub-gate 223a.

The third sub-gate 223d may be spaced apart from the first sub-gate 223a. For example, the second sub-channel 221c2 may be disposed between the first sub-channel 221c1 and the third sub-channel 221c3. Thus, in the display apparatus according to another embodiment of the present disclosure, a channel formed in the second sub-channel 221c2 of each pixel area PA may function as an effective channel of the second thin film transistor in the corresponding pixel area. And, in the display apparatus according to another embodiment of the present disclosure, a channel formed in the first sub-channel 221c1 and a channel formed in the third sub-channel 221c3 of each pixel area may function as a lightly doped drain (LDD) region of the second thin film transistor in the corresponding pixel area. For example, the amount of oxygen contained in the first sub-channel 221c1 and the amount of oxygen contained in the third sub-channel 221c3 may be different from the amount of oxygen contained in the second sub-channel 221c2. Therefore, in the display apparatus according to another embodiment of the present disclosure, the driving current of the second thin film transistor in each pixel area may be increased, and deterioration in the characteristics of the corresponding second thin film transistor due to hot carrier effect may be prevented.

The display apparatus according to the embodiment of the present disclosure is described that the second sub-gate 223b may include a region overlapping with the first sub-gate 223a. However, in the display apparatus according to another embodiment of the present disclosure, the second gate electrode 223 of each pixel area PA may include a plurality of sub-gate patterns, which are disposed on a different layer from the first sub-gate 223a. For example, in the display apparatus according to another embodiment of the present disclosure, the second gate electrode of each pixel area may include a first sub-gate pattern 223b1 and a second sub-gate pattern 223b2, which are disposed on a different layer from the first sub-gate 223a, as shown in FIG. 10. The second sub-gate pattern 223b2 may be spaced apart from the first sub-gate pattern 223b1. The first sub-gate pattern 223b1 may also be referred to as a second sub-gate of the second gate electrode 223, and the second sub-gate pattern 223b2 may also be referred to as a three sub-gate of the second gate electrode 223. For example, the first sub-gate 223a may include a region overlapping with a space between the first sub-gate pattern 223b1 and the second sub-gate pattern 223b2. The second sub-gate pattern 223b2 may be disposed on a same layer as the first sub-gate pattern 223b1. The second sub-gate pattern 223b2 may include a same material as the first sub-gate pattern 223b1. The second sub-gate pattern 223b2 may be formed by a same process as the first sub-gate pattern 223b1. For example, the second sub-gate pattern 223b2 may be formed simultaneously with the first sub-gate pattern 223b1.

The first sub-gate pattern 223b1 may overlap the second sub-channel 221c2. The second sub-gate pattern 223b2 may overlap the third sub-channel 221c3. For example, a distance between the third sub-channel 221c3 and the second sub-gate pattern 223b2 may be a same as a distance between the second sub-channel 221c2 and the first sub-gate pattern 223b1. A channel of the third sub-channel 221c3 may be formed simultaneously with a channel of the second sub-channel 221c2. A distance between the first sub-channel 221c1 and the first sub-gate 223a may be smaller than the distance between the second sub-channel 221c2 and the first sub-gate pattern 223b1 and the distance between the third sub-channel 221c3 and the second sub-gate pattern 223b2. Thus, in the display apparatus according to another embodiment of the present disclosure, the driving current generated by the second thin film transistor of each pixel area and the S-factor of the corresponding second thin film transistor may be effectively increased. That is, in the display apparatus according to another embodiment of the present disclosure, the degree of freedom in configuration of the second gate electrode may be improved. The amount of oxygen contained in the second sub-channel 221c2 and the amount of oxygen contained in the third sub-channel 221c3 may be different from the amount of oxygen contained in the first sub-channel 221c1.

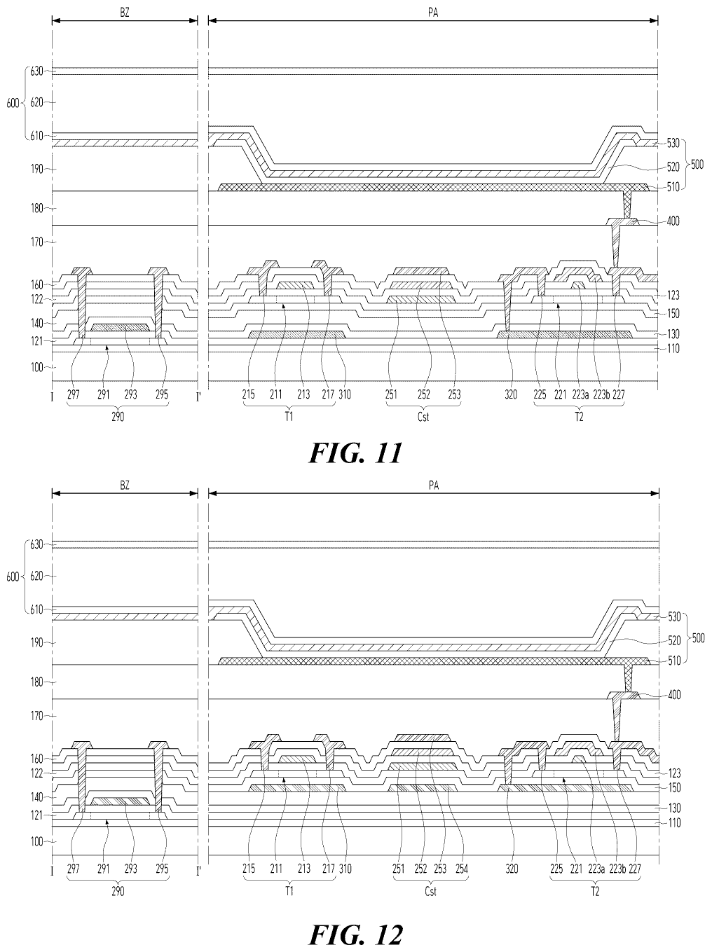

The display apparatus according to the embodiment of the present disclosure is described that a distance between the second light-blocking pattern 320 and the second semiconductor pattern 221 of each pixel area PA may be smaller than a distance between the first light-blocking pattern 310 and the first semiconductor pattern 211. However, in the display apparatus according to another embodiment of the present disclosure, the second light-blocking pattern 320 of each pixel area PA may be disposed on a same layer as the first light-blocking pattern 310 of the corresponding pixel area PA. For example, in the display apparatus according to another embodiment of the present disclosure, the second light-blocking pattern 320 of each pixel area PA may be disposed between the first gate insulating layer 121 and the lower interlayer insulating layer 130, as shown in FIG. 11. The second light-blocking pattern 320 of each pixel area PA may include a same material as the circuit gate electrode 293. The light-blocking pattern 320 of each pixel area PA may be formed by a same process as the circuit gate electrode 293. For example, the second light-blocking pattern 320 of each pixel area PA may be formed simultaneously with the circuit gate electrode 293. Thus, in the display apparatus according to another embodiment of the present disclosure, difference in the S-factor of the first thin film transistor T1 and the second thin film transistor T2 in each pixel area PA may be determined by the location of the second sub-gate 223b. For example, in the display apparatus according to another embodiment of the present disclosure, difference between the S-factor of the first thin film transistor T1 and the S-factor of the second thin film transistor T2 in each pixel area PA may be proportional to a thickness of the third gate insulating layer 123 in the corresponding pixel area PA. Therefore, in the display apparatus according to the embodiment of the present disclosure, process efficiency may be improved, occurrence of stain may be prevented when a low gray-scale image is realized, and efficiency of each pixel driving circuit may be improved.

In the display apparatus according to another embodiment of the present disclosure, the first light-blocking pattern 310 and the second light-blocking pattern 320 of each pixel area PA may be disposed between the separation insulating layer 140 and the upper buffer layer 150, as shown in FIG. 12. The storage capacitor Cst of each pixel area PA may include a fourth capacitor electrode 254 disposed on a same layer as the first light-blocking pattern 310 and the second light-blocking pattern 320 of the corresponding pixel area PA. The fourth capacitor electrode 254 of each pixel area PA may include a same material as the first light-blocking pattern 310 and the second light-blocking pattern 320 of the corresponding pixel area PA. The fourth capacitor electrode 254 of each pixel area PA may be formed by a same process as the first light-blocking pattern 310 and the second light-blocking pattern 320 of the corresponding pixel area PA. For example, the fourth capacitor electrode 254 of each pixel area PA may be formed simultaneously with the first light-blocking pattern 310 and the second light-blocking pattern 320 of the corresponding pixel area PA. Thus, in the display apparatus according to another embodiment of the present disclosure, decrease in process efficiency may be prevented, and a size occupied by the storage capacitor Cst of each pixel area PA may be minimized. Therefore, in the display apparatus according to another embodiment of the present disclosure, the degree of freedom in configuration of the pixel driving circuit in each pixel area PA may be improved.

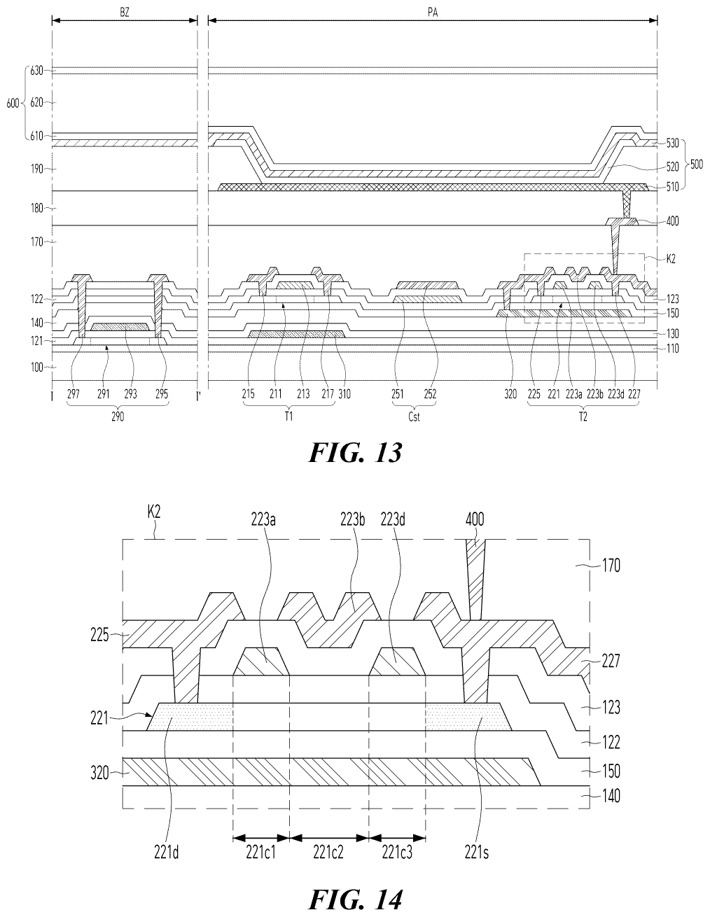

The display apparatus according to the embodiment of the present disclosure is described that the second sub-gate 223b of each pixel area PA may be disposed on a different layer from the second drain electrode 225 and the second source electrode 227 of the corresponding pixel area PA. However, in the display apparatus according to another embodiment of the present disclosure, the second sub-gate 223b of each pixel area PA may be disposed on a same layer as the second drain electrode 225 and the second source electrode 227 of the corresponding pixel area PA, as shown in FIGS. 13 and 14. The second sub-gate 223b of each pixel area PA may be spaced apart from the second drain electrode 225 and the second source electrode 227 of the corresponding pixel area PA. The second sub-gate 223b of each pixel area PA may include a same material as the second drain electrode 225 and the second source electrode 227 of the corresponding pixel area PA. The second sub-gate 223b of each pixel area PA may be formed by a same process as the second drain electrode 225 and the second source electrode 227 of the corresponding pixel area PA. For example, the second sub-gate 223b of each pixel area PA may be formed simultaneously with the second drain electrode 225 and the second source electrode 227 of the corresponding pixel area PA. Thus, in the display apparatus according to another embodiment of the present disclosure, deterioration of process efficiency may be minimized, and the driving current generated by the second thin film transistor T2 of each pixel area PA and the S-factor of the corresponding second thin film transistor T2 may be increased.

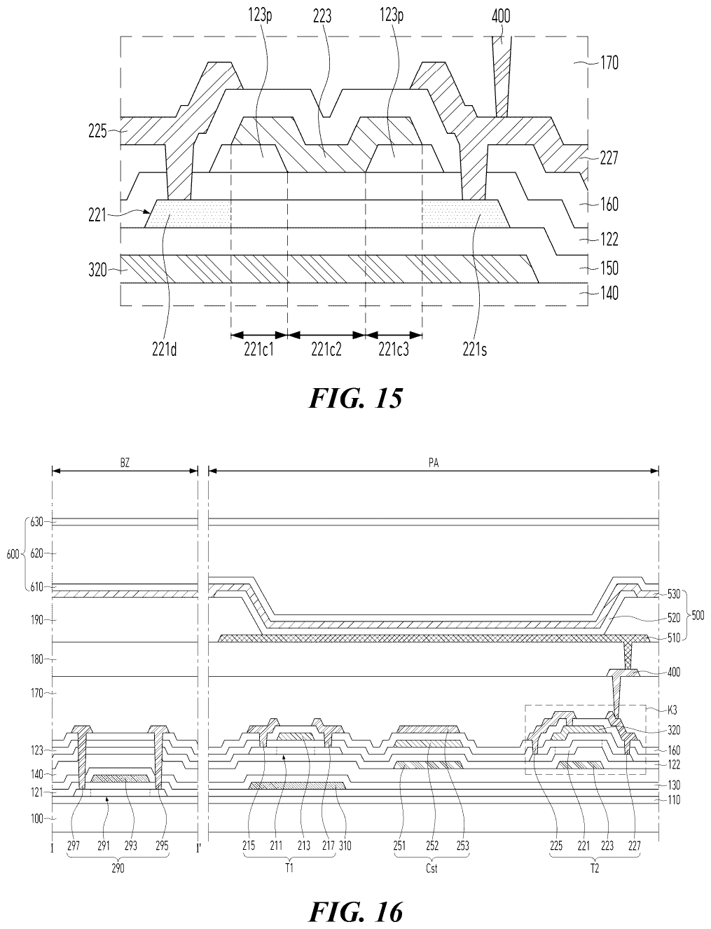

The display apparatus according to the embodiment of the present disclosure is described that the second gate electrode 223 of each pixel area PA may include the first sub-gate 223a and the second sub-gate 223b disposed on a different layer from the first sub-gate 223a. However, in the display apparatus according to another embodiment of the present disclosure, the second gate electrode 223 of each pixel area PA may be formed to have a single pattern, which is physically connected. For example, in the display apparatus according to another embodiment of the present disclosure, insulating patterns 123p overlapping with the first sub-channel 221c1 and the third sub-channel 221c3 may be disposed on the second gate insulating layer 122, both ends of the second gate electrode 223 on the second sub-channel 221c2 may be disposed on the insulating patterns 123p, as shown in FIG. 15. A distance between each of the two ends of the second gate electrode 223 and a corresponding one of the first sub-channel 221c1 and the third sub-channel 221c3 is greater than a distance between a portion of the second gate electrode 223 extending between the two ends and the second sub-channel 221c2. The two ends of the second gate electrode 223 may be referred to as second and third sub-gates of the second gate electrode 223, respectively, and the portion of the second gate electrode 223 may also be referred to as a first sub-gate of the second gate electrode 223. The first, second, and third sub-gates are formed as single pattern and are disposed on the same layer. Thus, in the display apparatus according to another embodiment of the present disclosure, a channel of the second sub-channel 221c2 may be formed before a channel of the first sub-channel 221c1 and a channel of the third sub-channel 221c3. That is, in the display apparatus according to another embodiment of the present disclosure, a channel of the first sub-channel 221c1 and a channel of the third sub-channel 221c3 may function as an effective channel of the corresponding second thin film transistor. Therefore, in the display apparatus according to another embodiment of the present disclosure, a process of forming the second gate electrode 223 may be simplified, occurrence of stain may be prevented when a low gray-scale image is realized, and efficiency of each pixel driving circuit may be improved. It should be appreciated that the insulating patterns 123p may provided by a separate insulating layer such as the third insulating layer 123, or may be a portion of the second gate insulating layer 122.

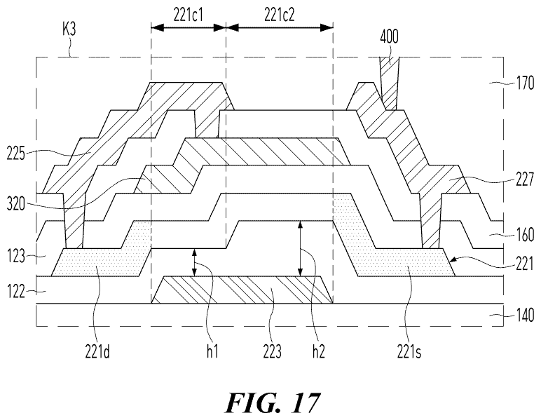

The display apparatus according to the embodiment of the present disclosure is described that the second semiconductor pattern 221 of each pixel area PA may be disposed between the device substrate 100 and the second gate electrode 223 of the corresponding pixel area PA. However, in the display apparatus according to another embodiment of the present disclosure, a structure of the second thin film transistor T2 in each pixel area PA may be different from a structure of the first thin film transistor T1 in the corresponding pixel area PA. For example, in the display apparatus according to another embodiment of the present disclosure, the second gate electrode 223 of each pixel area PA may be disposed between the device substrate 100 and the second semiconductor pattern 221 of the corresponding pixel area PA, as shown in FIGS. 16 and 17. The second gate insulating layer 122 between the second gate electrode 223 and the second semiconductor pattern 221 may include a region having a first thickness h1 and a region having a second thickness h2. The second thickness h2 may be greater than the first thickness h1. That is, in the display apparatus according to another embodiment of the present disclosure, the second channel region of the second semiconductor pattern 221 may include a first sub-channel 221c1 spaced apart from a first portion of the second gate electrode 223 by the first thickness h1, and a second sub-channel 221c2 spaced apart from a second portion of the second gate electrode 223 by the second thickness h2. The first portion of the second gate electrode 223 may also be referred to as a first sub-gate of the second gate electrode 223, and the second portion of the second gate electrode 223 may also be referred to as a second sub-gate of the second gate electrode 223. A channel of the first sub-channel 221c1 may be formed before a channel of the second sub-channel 221c2. Thus, in the display apparatus according to another embodiment of the present disclosure, a channel in the second sub-channel 221c2 of each pixel area PA may function as an effective channel of the second thin film transistor T2 in the corresponding pixel area PA. Therefore, in the display apparatus according to another embodiment of the present disclosure, the S-factor of the second thin film transistor T2 in each pixel area PA may be adjusted by the thickness a difference between the first thickness h1 and the second thickness h2.

The first thickness h1 may be a same as a distance between the first semiconductor pattern 211 and the first gate electrode 213 of each pixel area PA. The second light-blocking pattern 320 overlapping with the second channel region of the second semiconductor pattern 221 may be disposed between the third gate insulating layer 123 and the upper interlayer insulating layer 160 of each pixel area PA. The second light-blocking pattern 320 of each pixel area PA may be disposed on a same layer as the first gate electrode 213 of the corresponding pixel area PA. The second light-blocking pattern 320 of each pixel area PA may include a same material as the first gate electrode 213 of the corresponding pixel area PA. The second light-blocking pattern 320 of each pixel area PA may be formed by a same process as the first gate electrode 213 of the corresponding pixel area PA. For example, the second light-blocking pattern 320 of each pixel area PA may be formed simultaneously with the first gate electrode 213 of the corresponding pixel area PA. Thus, in the display apparatus according to another embodiment of the present disclosure, the S-factor of the second thin film transistor T2 in each pixel area PA and the driving current generated by the corresponding second thin film transistor T2 may be increased, regardless of a structure of the second thin film transistor T2 in each pixel area PA. Therefore, in the display apparatus according to another embodiment of the present disclosure, efficiency of the pixel driving circuit in each pixel area PA may be improved. And, in the display apparatus according to another embodiment of the present disclosure, lower power driving may be possible, and power consumption may be reduced.

In the result, the display apparatus according to the embodiments of the present disclosure may comprise the thin film transistor electrically connected to the light-emitting device, wherein the semiconductor pattern of the thin film transistor may include the first sub-channel and the second sub-channel, wherein the gate electrode of the thin film transistor may include a first sub-gate overlapping with the first sub-channel and a second sub-gate overlapping with the second sub-channel, wherein the second threshold voltage applied to the second sub-gate at the moment that a channel is formed in the second sub-channel may be different from the first threshold voltage applied to the first sub-gate at the moment that a channel is formed in the first sub-channel. Thus, in the display apparatus according to the embodiments of the present disclosure, the S-factor of the thin film transistor may be increased, without decreasing a channel length of the thin film transistor. That is, in the display apparatus according to the embodiments of the present disclosure, occurrence of stains may be prevented, when a low gray-scale image is realized, and the driving current generated by the thin film transistor may be increased. Thereby, in the display apparatus according to the embodiments of the present disclosure, process efficiency and quality of the image may be improved. And, in the display apparatus according to the embodiments of the present disclosure, power consumption may be reduced by lower power driving.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a pixel driving circuit including a thin film transistor; and
a light-emitting device electrically connected to the pixel driving circuit,
wherein a gate electrode of the thin film transistor includes a first sub-gate and a second sub-gate between a drain electrode and a source electrode of the thin film transistor,
wherein a semiconductor pattern of the thin film transistor includes a first sub-channel overlapping with the first sub-gate and a second sub-channel overlapping with the second sub-gate, and
wherein a distance between the second sub-channel and the second sub-gate is greater than a distance between the first sub-channel and the first sub-gate.

2. The display apparatus according to claim 1, wherein a number of insulating layers disposed between the second sub-channel and the second sub-gate is greater than a number of insulating layers disposed between the first sub-channel and the first sub-gate, such that the distance between the second sub-channel and the second sub-gate is greater than the distance between the first sub-channel and the first sub-gate.

3. The display apparatus according to claim 2, wherein the semiconductor pattern includes a drain region electrically connected to the drain electrode and a source region electrically connected to the source electrode, and
wherein the first sub-channel and the second sub-channel are disposed in parallel to each other between the drain region and the source region.

4. The display apparatus according to claim 2, wherein the second sub-gate is disposed on a different layer from the first sub-gate.

5. The display apparatus according to claim 4, wherein the gate electrode further includes a third sub-gate disposed on a same layer as the second sub-gate,
wherein the semiconductor pattern further includes a third sub-channel overlapping with the third sub-gate, and
wherein the first sub-channel is disposed between the second sub-channel and the third sub-channel, and the first sub-channel, the second sub-channel, and the third sub-channel are disposed parallel to each other between the drain region and the source region.

6. The display apparatus according to claim 5, wherein the second sub-gate is spaced apart from the third sub-gate, and the first sub-gate includes a region overlapping with a space between the second sub-gate and the third sub-gate.

7. The display apparatus according to claim 4, wherein the gate electrode further includes a third sub-gate disposed on a same layer as the first sub-gate and spaced apart from the first sub-gate,
wherein the semiconductor pattern further includes a third sub-channel overlapping with the third sub-gate, and
wherein the second sub-channel is disposed between the first sub-channel and the third sub-channel, and the first sub-channel, the second sub-channel, and the third sub-channel are disposed parallel to each other between the drain region and the source region.

8. The display apparatus according to claim 4, wherein the semiconductor pattern further includes a third sub-channel, the first sub-channel is disposed between the second sub-channel and the third sub-channel, and the first sub-channel, the second sub-channel, and the third sub-channel are disposed parallel to each other between the drain region and the source region,
wherein the second sub-gate overlaps with the first sub-channel, the second sub-channel and the third sub-channel, and
wherein the first sub-gate is disposed between the first sub-channel and the second sub-gate, and the second sub-channel and the third sub-channel are disposed outside the first sub-gate.

9. The display apparatus according to claim 5, wherein the semiconductor pattern is made of an oxide semiconductor, and
wherein the amount of oxygen contained in the second sub-channel and the amount of oxygen contained in the third sub-channel are different from the amount of oxygen contained in the first sub-channel.

10. The display apparatus according to claim 7, wherein the semiconductor pattern is made of an oxide semiconductor, and
wherein the amount of oxygen contained in the first sub-channel and the amount of oxygen contained in the third sub-channel are different from the amount of oxygen contained in the second sub-channel.

11. The display apparatus according to claim 4, wherein the drain electrode and the source electrode are disposed on a different layer from the first sub-gate and from the second sub-gate.

12. The display apparatus according to claim 11, wherein the gate electrode further includes a connection gate electrically connecting the second sub-gate to the first sub-gate, and
wherein the connection gate is disposed on a same layer as the drain electrode and the source electrode.

13. The display apparatus according to claim 4 wherein the drain electrode and the source electrode are disposed on a same layer as the second sub-gate.

14. The display apparatus according to claim 4, wherein the pixel driving circuit further includes a storage capacitor electrically connected between the source electrode and the gate electrode,
wherein the storage capacitor includes a first capacitor electrode disposed on a same layer as the first sub-gate and a second capacitor electrode disposed on a same layer as the second sub-gate.

15. The display apparatus according to claim 14, further comprising:
a device substrate supporting the pixel driving circuit and the light-emitting device; and
a light-blocking pattern disposed between the device substrate and the semiconductor pattern,
wherein the storage capacitor includes a third capacitor electrode disposed on a same layer as the light-blocking pattern.

16. The display apparatus according to claim 3, wherein the second sub-gate is disposed on a same layer as the first sub-gate.

17. The display apparatus according to claim 16, wherein the gate electrode further includes a third sub-gate disposed on a same layer as the first sub-gate and the second sub-gate, the first sub-gate extends between the second sub-gate and the third sub-gate,
wherein the semiconductor pattern further includes a third sub-channel overlapping with the third sub-gate,
wherein the first sub-channel is disposed between the second sub-channel and the third sub-channel, and the first sub-channel, the second sub-channel, and the third sub-channel are disposed parallel to each other between the drain region and the source region, and
wherein the number of insulating layers disposed between the third sub-channel and the third sub-gate is greater than the number of insulating layers disposed between the first sub-channel and the first sub-gate, such that a distance between the third sub-channel and the third sub-gate is greater than the distance between the first sub-channel and the first sub-gate.

18. The display apparatus according to claim 1, wherein the first sub-gate is spaced from the first sub-channel by a first region of an insulating layer having a first thickness,
wherein the second sub-gate is spaced from the second sub-channel by a second region of the insulating layer having a second thickness, and
wherein the first thickness is greater than the second thickness.

19. The display apparatus according to claim 1, wherein the thin film transistor is a driving thin film transistor for the light-emitting device.

20. A display apparatus comprising:
a first thin film transistor on a pixel area of a device substrate, the first thin film transistor including a first semiconductor pattern and a first gate electrode;
a second thin film transistor on the pixel area of the device substrate, the second thin film transistor including a second semiconductor pattern and a second gate electrode;
a planarization layer on the device substrate, the first thin film transistor and the second thin film transistor being covered by the planarization layer; and
a light-emitting device on the planarization layer in the pixel area, the light-emitting device electrically connected to the second thin film transistor,
wherein the second semiconductor pattern includes a first sub-channel and a second sub-channel, which are disposed in parallel to each other between a drain region and a source region of the second semiconductor pattern,
wherein the second gate electrode includes a first sub-gate on the first sub-channel and a second sub-gate on the second sub-channel, and
wherein a distance between the second sub-channel and the second sub-gate is greater than a distance between the first sub-channel and the first sub-gate.

21. The display apparatus according to claim 20, wherein the distance between the first sub-channel and the first sub-gate is a same as a distance between the first semiconductor pattern and the first gate electrode.

22. The display apparatus according to claim 20, wherein the second sub-gate includes a same material as the first sub-gate, and is disposed on a same layer as the first sub-gate.

23. The display apparatus according to claim 22, wherein the second sub-gate is in contact with the first sub-gate on the second semiconductor pattern.

24. The display apparatus according to claim 20, wherein the second semiconductor pattern is made of an oxide semiconductor, and
wherein an amount of oxygen contained in the first sub-channel and an amount of oxygen contained in the second sub-channel are larger than an amount of oxygen contained in the drain region and an amount of oxygen contained in the source region.

25. The display apparatus according to claim 24, wherein the amount of oxygen contained in the second sub-channel is a same as the amount of oxygen contained in the first sub-channel.

26. The display apparatus according to claim 20, wherein the first semiconductor pattern is disposed between the device substrate and the first gate electrode, and the second gate electrode is disposed between the device substrate and the second semiconductor pattern.

27. The display apparatus according to claim 20, wherein the first thin film transistor is a switching thin film transistor, and the second thin film transistor is a driving thin film transistor.
